(19) United States
(12) Patent Application Publication
(10) Pub. No.: US 2026/0075740 A1
(43) Pub. Date: Mar. 12, 2026

(54) SCALABLE AND MODULAR AIRCRAFT SERVER CLUSTER IMPLEMENTATION

(71) Applicant: Panasonic Avionics Corporation, Irvine, CA (US)

(72) Inventors: Matthew ASLIN, San Juan Capistrano, CA (US); Andrew BARNES, Mission Viejo, CA (US); Calvin CHING, Arcadia, CA (US); Nolan CLAPP, Yorba Linda, CA (US); Dan CLARK, Long Beach, CA (US); Yichao JIANG, Irvine, CA (US); Melvin LAHIP, Foothill Ranch, CA (US); Tom PETERSON, Huntington Beach, CA (US); Martin PROEPPER, Corona, CA (US); Mark SETELE, Ladera Ranch, CA (US); Yuqi YANG, Irvine, CA (US)

(21) Appl. No.: 19/235,329

(22) Filed: Jun. 11, 2025

Related U.S. Application Data
(63) Continuation of application No. 19/171,094, filed on Apr. 4, 2025.
(60) Provisional application No. 63/692,614, filed on Sep. 9, 2024.

(51) Int. Cl. H05K 7/14; B64D 43/00

(52) U.S. Cl. CPC H05K 7/1487; B64D 43/00; H05K 7/1492

(57) ABSTRACT

Scalable and modular aircraft servers for aircraft and associated systems, devices, and methods are disclosed herein. A headend server can include a chassis meeting a 6 Modular Concept Unit (MCU) size requirement, a pair of modules insertable into and removable from the chassis, one or more electronic blades, an I/O interface module housed in the chassis, and a power supply integrated in the chassis. Each module can include a plurality of slots, and the one or more electronic blades can be shaped and sized to fit in corresponding ones of the plurality of slots. Each of the headend server and the pair of modules can be a Line Replacement Unit (LRU). The headend server can be configured to provide a common operational interface between multiple types of aircrafts and the one or more electronic blades.

### CROSS-REFERENCE TO RELATED APPLICATION(S)

The present application is a continuation of U.S. patent application Ser. No. 19/171,094, filed Apr. 4, 2025, entitled “SCALABLE AND MODULAR AIRCRAFT SERVER CLUSTER IMPLEMENTATION”, which claims the benefit of U.S. Provisional Patent Application No. 63/692,614, filed Sep. 9, 2024, entitled “SCALABLE AND MODULAR AIRCRAFT SERVER CLUSTER IMPLEMENTATION,” the disclosure of which is incorporated herein by reference in its entirety.

### TECHNICAL FIELD

This application is related to the operation of an in-flight entertainment system and more particularly to scalable and modular aircraft servers.

### BACKGROUND

Commercial travel has evolved to provide entertainment options to passengers traveling to their destinations. For example, in an airplane or train, entertainment options are provided on monitors located on the back of seats, where the monitors can enable passengers to watch movies or television shows as they travel to their destinations. Passenger vehicles have also begun to provide connectivity tools that may provide additional opportunities to passengers for entertainment or productivity.

### SUMMARY

The present document provides various techniques that may be used to implement an in-flight entertainment and communication (IFEC) server onboard an airplane. Some embodiments of the present technology are directed to headend servers that can offer twice the performance in half the physical size compared to existing servers. The headend servers disclosed herein can also provide high degrees of compatibility, modularity, scalability, performance. For example, the headend servers can be packaged in a single 6 Modular Concept Unit (MCU) form factor chassis, offering flexibility and scalability. The headend servers can include copper or fiber interfaces, ensuring compatibility with all aircraft networks. The headend servers can support various inserts, including compute modules, high-capacity storage, artificial intelligence (AI) modules, and/or the like. The headend servers can support hosting, deploying, and monitoring of applications, and can handle various operational, cabin, and passengers needs such as Over-the-Top (OTT) streaming, edge caching, virtualization, and data collection. In some embodiments, each chassis accommodates up to two removable, independent modules. The dual-module design can provide internal redundancy and thereby reduce the need for extra servers, and can offer improved performance and features in a smaller footprint and reduced cost compared to existing servers. The headend servers disclosed herein can also be both backward and forward compatible.

In one example aspect, an electronic system is disclosed. The system includes a chassis comprising at least one chassis processor, wherein the chassis is configured with N slots for accepting N electronic blades comprising zero or more of compute blades and zero or more of storage blades, where N is a positive integer greater than 1; wherein the at least one chassis processor is configured to provide a common operational interface between multiple types of aircrafts and the N electronic blades.

In another example aspect, a method of operating an electronic equipment is disclosed. The method includes providing a chassis on an aircraft, wherein the chassis includes at least one chassis processor, wherein the chassis is configured with N slots for accepting N electronic blades comprising zero or more of compute blades and zero or more of storage blades, where N is a positive integer greater than 1; wherein the at least one chassis processor is configured to provide a common operational interface between multiple types of aircrafts and the N electronic blades, and populating the N slots with compute blades and/or storage blades according to a target configuration.

In yet another aspect, an apparatus comprising one or more processors configured to implement the described methods is disclosed.

In yet another aspect, a computer readable medium is disclosed. The computer readable medium stores processor-executable program code that, upon execution by one or more processors, causes implementation of a method described in the present document.

These, and other aspects are disclosed throughout the present document.

### BRIEF DESCRIPTION OF THE DRAWINGS

FIG. 1 shows an exemplary airplane depicting an IFE installation.

FIG. 2 shows an example of a system for sensor data collection and analysis.

FIG. 3 shows an example of a rule-based system for sensor data analysis.

FIG. 4A shows an airline network for sensor data capture and analysis.

FIG. 4B shows a multiple-airline network for sensor data capture and analysis.

FIG. 5 shows an example of an in-flight entertainment network.

FIG. 6 shows an example of an existing server system.

FIG. 7 shows an example of a proposed modular configuration configured in accordance with various embodiments of the present technology.

FIG. 8 shows an example of a chassis with 6-Modular Concept Units (MCU) configured in accordance with various embodiments of the present technology.

FIG. 9 shows an example compute blade configuration configured in accordance with various embodiments of the present technology.

FIG. 10 shows an example storage blade configuration configured in accordance with various embodiments of the present technology.

FIG. 11 shows an example of a chassis configured in accordance with various embodiments of the present technology.

FIG. 12 shows an example of a fiber specific input output module configured in accordance with various embodiments of the present technology.

FIG. 13 is an example of a copper centric input output module configured in accordance with various embodiments of the present technology.

FIG. 14 is an example of an onboard server and a legacy interface server configured in accordance with various embodiments of the present technology.

FIG. 15 shows an example of a system implementation configured in accordance with various embodiments of the present technology.

FIG. 16 shows a system integration with seatback electronics configured in accordance with various embodiments of the present technology.

FIG. 17 shows various possible configurations of a modular server configured in accordance with various embodiments of the present technology.

FIGS. 18A-18C are front perspective, top, and front views, respectively, of an aircraft server configured in accordance with various embodiments of the present technology.

FIG. 19 is a rear perspective view of a server module configured in accordance with various embodiments of the present technology.

FIG. 20A is a perspective view of an aircraft server including latches configured in accordance with various embodiments of the present technology.

FIG. 20B is a perspective view of a server module including a latch and configured in accordance with various embodiments of the present technology.

FIG. 21 illustrates multi-processor sub-systems with software defined storage and configured in accordance with various embodiments of the present technology.

FIG. 22 illustrates the storage expansion ability of servers configured in accordance with various embodiments of the present technology.

FIG. 23 illustrates PCIe GPU/AI accelerators and mixed use abilities in accordance with various embodiments of the present technology.

FIG. 24 illustrates multi-processor subsystems with cluster and IFE networking in accordance with various embodiments of the present technology.

FIG. 25 is a schematic diagram of a server chassis configured in accordance with various embodiments of the present technology.

FIG. 26 is a schematic diagram of an artificial intelligence (AI) accelerator module configured in accordance with various embodiments of the present technology.

FIG. 27 is a schematic diagram illustrating connectivity within a server configured in accordance with various embodiments of the present technology.

FIG. 28 is a schematic diagram illustrating connectivity within another server configured in accordance with various embodiments of the present technology.

FIG. 29 is a cross-sectional view of a server module configured in accordance with various embodiments of the present technology.

FIG. 30 is a schematic top view of adjacent server modules, illustrating thermal management in accordance with various embodiments of the present technology.

FIG. 31 is a schematic diagram illustrating an operations management system of a server on an aircraft, configured in accordance with various embodiments of the present technology.

FIGS. 32 and 33 are schematic cross-sectional side views of the server.

FIG. 34 is a schematic top view of the server illustrating airflow.

FIGS. 35A and 35B are schematic top and bottom views, respectively, of the server illustrating sensor positioning.

FIG. 36 is a schematic diagram illustrating data post-processing flow in accordance with various embodiments of the present technology.

FIG. 37 is a schematic diagram illustrating operation of a trained neural network model 3700 configured in accordance with embodiments of the present technology.

FIG. 38 is a flowchart for an example method disclosed in the present document.

### DETAILED DESCRIPTION

### 1. Introduction

Among the many advancements in aircraft technology, improvements in passenger comfort and convenience have received much attention. Air travel typically involves journeys over extended distances that at the very least take several hours to complete, so airlines provide onboard in-flight entertainment and communications (IFEC) systems that offer a wide variety of multimedia content for passenger enjoyment. Recently released movies are a popular viewing choice, as are television shows such as news programs, situation and stand-up comedies, documentaries, and so on. Useful information about the destination such as airport disembarking procedures, immigration and custom procedures and the like are also frequently presented. Audio-only programming is also available, typically comprised of playlists of songs fitting into a common theme or genre. Likewise, video-only content such as flight progress mapping, flight status displays, and so forth are available. Many in-flight entertainment systems also include video games that may be played by the passenger.

The specific installation may vary depending on service class, though in general, each passenger seat is equipped with a display device, an audio output modality, an input modality, and a terminal unit. The terminal unit may generate video and audio signals, receive inputs from the input modality, and execute pre-programmed instructions in response thereto. The display device is typically an LCD screen that is installed on the seatback of the row in front of the passenger, though in some cases it may be mounted to a bulkhead or retractable arm, or the like, which is in turn mounted to the passenger's seat. Furthermore, the audio output modality is a headphone jack, to which a headphone, either supplied by the airline or by the passenger, may be connected. Inputs to the terminal unit may be provided via a separate multi-function remote controller or by via a combination touch display. Although the terminal unit and display device were separate components in earlier IFEC implementations, more recently, these components and more may be integrated into a single smart monitor.

The multimedia content is encoded and stored as digital data, with a video decoder and audio decoder of the terminal unit functioning to generate the aforementioned video and audio signals therefrom. It is desirable to have a wide range of different multimedia content to satisfy the varying tastes of passengers. It is also desirable to have a sufficient volume of multimedia content so that passengers can remain occupied with entertainment for the entire duration of the flight. Accordingly, the multimedia content stored onboard the aircraft can range in the hundreds of gigabytes, if not over a terabyte. The majority of the data comprises the video programming, although the audio and video game content may be significant as well. This data is typically not stored on each individual terminal unit, but rather, in a central content server also onboard the aircraft. In this regard, the terminal unit is understood to incorporate networking modalities such as Ethernet to establish data communications with the central content server. Once a particular selection of multimedia content is requested by the passenger via the content selection application, the terminal unit may retrieve the same from the central content server, decode the data, and present it to the passenger.

Because the personal tastes and preferences of passengers can vary considerably, airlines maintain a wide range of multimedia content onboard the content server. Furthermore, in addition to variety of volume, novelty is as important for airlines to keep its passengers engaged with the in-flight entertainment system, particularly for valuable frequent fliers. A variety of modalities, including portable content loaders, wireless modules, and the like may be used to load sets of multimedia content to the content server. The content update process typically takes place on a monthly schedule, preferably during a layover between flights, such as when aircraft maintenance is conducted. For each item of multimedia content loaded on to the IFEC system in this way, however, the airlines must pay a fee. Specifically, the charges are based upon the size of the multimedia content set loaded, as well as the number of cycles or intervals over which the multimedia content is maintained on an aircraft. Scaled to an entire fleet of aircraft, these charges may be substantial, and because they are levied against the entire content set that is loaded on the aircraft, airlines are being charged for content that is viewed less frequently and/or not being viewed at all.

Additionally, there is a growing trend to allow passengers to use their personal electronic devices (PEDs) (e.g., smartphone, laptops, or tablets) for entertainment, which allows passengers to minimize having to touch a commonly exposed surface. The audio or video content provided by the IFEC platform to the PED may include movies, television shows, or other content such as advertisements or flight safety video. Each seatback device has an enclosure that can have a processor executing custom software programs to receive messages or commands from an edge server and to display visual content on a display of the seatback device and to output sound to a headphone jack. Conventional in-vehicle entertainment systems can also wirelessly transmit audio or video content to PEDs that belong to passengers.

The above-described passenger amenities and services are provided using an electronic network that includes video servers, wiring, seatback displays, card readers, wireless network equipment, satellite transmission and reception equipment and so on. Deployment and maintenance of this equipment can be expensive, which requires the airlines to pay attention to which electronic systems and services are used by passengers more frequently or longer. Therefore, it is beneficial for airlines to measure and monitor use of various electronic equipment by passengers. For example, one benefit is to ensure passenger satisfaction, which may lead to the passenger preferring to travel on a particular airline. Another benefit is that airlines are able to find out the electronic systems that are popular and heavily used and may focus their maintenance and replacement resources to ensure that these electronic systems are available to passengers without minimum down time or errors. Situation: no standard way to quantify or qualify passenger engagement (in the cabin).

In the airlines industry, a variety of IFEC installment options are currently deployed. These solutions may include different IFE electronics vendors, different configuration of IFE deployments for different airplane models, different features of IFE systems offered by different airlines, or different types of IFE offered in different geographic areas. Such variations in the IFE deployments often make it difficult to measure effectiveness and use data of IFE electronics across different airlines, different IFE vendors, and different airplane models.

### 2. Exemplary Computing System and IFEC deployments

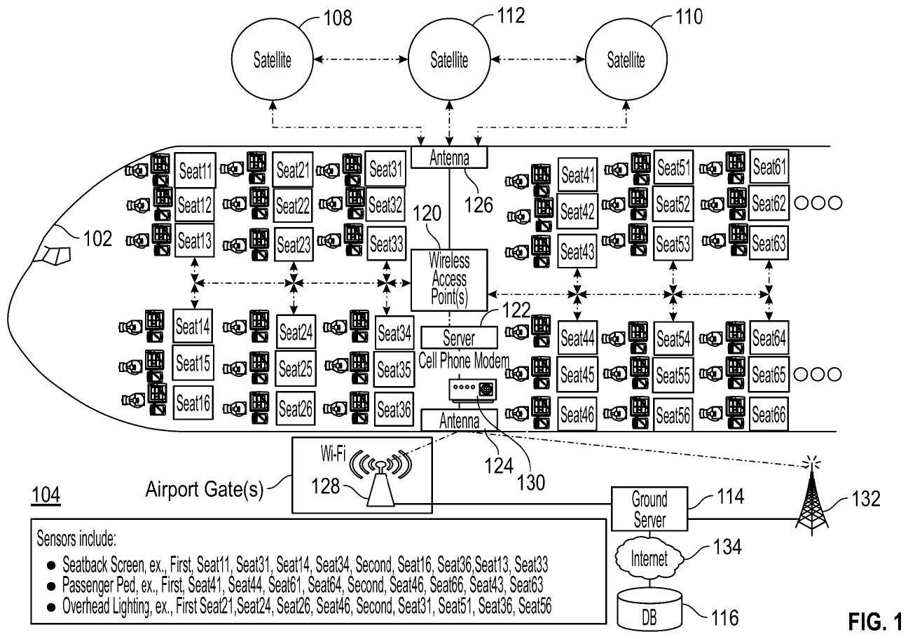

FIG. 1 shows an example system in which the various methods embodiments described in the present document may be implemented. An airplane 102 is depicted to include multiple passenger seats, Seat 11 to Seat 66. The airplane 102 may include an antenna 126 that is configured to communicate with external communication sources such as a satellite network that includes one or more satellites 108, 110, 112. Satellite communication may be used for both downloading information and uploading information. Wi-Fi 128 at airport gate(s) and Cell-phone modem 130 through a Cell Phone Tower 132 may be used to both downloading information and uploading information from/to ground server 114 through the Internet 134 and from/to database 116 as illustrated most notably in FIG. 1.

The airplane 102 may include an onboard server 122, one or more wireless access points 120 and an antenna 124 that is configured for communication with a ground server 114 that includes a database 116.

Also shown in FIG. 1 is an example of a script 104 that is used for collecting sensor data on the airplane 102. The script 104 may include a list of entries that show zones where sensor data, e.g., raw intrinsic data, raw extrinsic data, raw global data, is collected and ordered. For example, the first entry shows that seats 11, 31, 14, 34 are to be first, followed by seats 34, 16, 36, 13 and 33, and so on. Corresponding to each entry, there may be an onboard electronic device on passengers may be alerted for collecting sensor data from a sensor network, for example, including Seatback Display (illustrated by screen icon), Passenger PED (illustrated by cellular phone) and Overhead Lighting (illustrated by light bulb icon).

For example, for the above-listed seats, a message may be displayed on a seatback screen. For the next entry (corresponding to seats 41, 33, 61 and 64) a message may be sent to passengers' personal electronic devices (PEDs) for data sensor collection instructions, e.g., take a survey or complete a questionnaire, and/or as scripted for the sensor data collected by the sensor network about passengers about one or more aspects or incidents (e.g., when, during, what, before, during or at end one or more flights or destinations, number or quantity of or time of or time duration) in their trip, e.g., watching movies, browsing selected live television programs, sports casts, preferences for food, drink, and snack selections, cleanliness of the airplane, crew availability or helpfulness or resolving issues, informativeness of captain about flight and status to destination, and politeness and promptness of aircraft attendants. In one example, as illustrated in FIG. 1, seats 11, 31, 14, 34 (first) and seats 16, 36, 13, and 33 (second) are scripted as passengers for collecting sensor data from the sensor network, e.g., before flight, after flight at designated intervals or upon certain events (e.g., when, during, what, before, during or at end one or more flights or destinations, number or quantity of or time of or time duration), e.g., calling attendant, ordering food, ordering movies, surfing the Internet, using or clicking features of the Seatback Display or, and before, during, or upon deplaning; seats 41, 44, 61, 64 (first) and seats 46, 66, 43, 63 (second) are scripted as passengers for collecting sensor data from the sensor network before flight, after flight at designated intervals or upon certain events (e.g., when, during, what, before, during or at end one or more flights or destinations, number or quantity of or time of or time duration), and during deplaning; and seats 21, 24, 26, 46 (first) and seats 31, 51, 36, 56 (second) are scripted as passengers for collecting sensor data from the sensor network (e.g., when, during, what, before, during or at end one or more flights or destinations, number or quantity of or time of or time duration) before flight, after flight at designated intervals, and during deplaning.

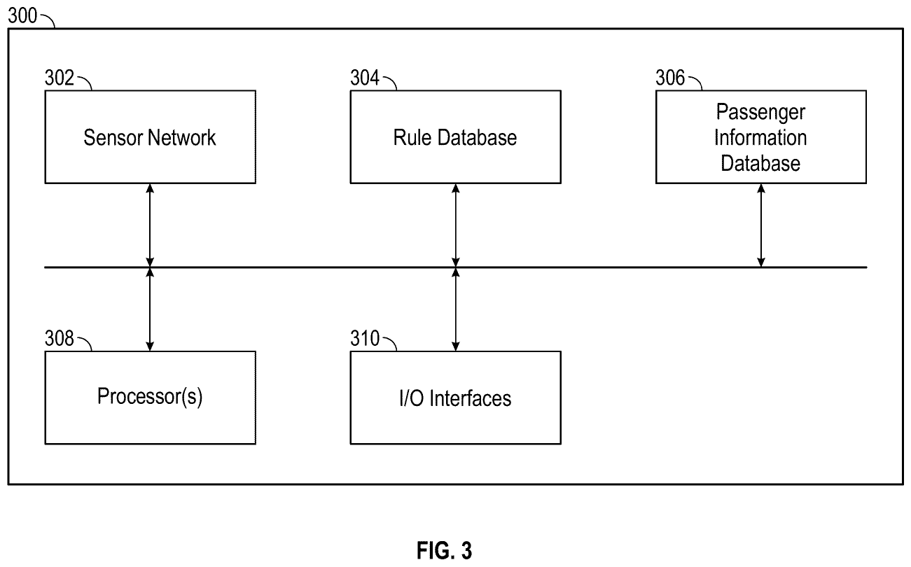

Continuing with FIG. 1, in some embodiments, passengers, individual passenger(s), and/or group(s) of passengers, and/or airline personnel can each select one or more mode(s) for collecting sensor data, e.g., Seatback Screen, overhead lighting, Passenger PED, for example, by entry into to a Seatback Screen, a passenger manifest, or an airline companion app downloaded on a mobile device (a Passenger PED) of a passenger. In some embodiments, passengers and/or individual passenger(s) and/or group(s) of passengers are selected for collecting sensor data in accordance with one or more screening criteria, e.g., when, how often, how, . . . or combinations thereof including: location of origin for flight, location of destination of flight, location of layover flight, news or history of events at origin, destination, or layover flight, monitor passenger health status during flight, traveling together family members, traveling together friends, business partners, and/or any other methods or systems described above or below, adjustments for collecting sensor data, when, how, how much, how often or ordering, for example, physical separation or time gap(s) between passenger seats (as illustrated in FIGS. 1 and 1), any empty seats or rows, or the like. In FIG. 1, the server 122 may be implemented using the device 300 described below with reference to FIG. 3. The server 122 may implement the script described in the present document. The wireless access points 120 may be used for prompting PEDs via messages to deplane. In some embodiments, the wireless access points may be used for detecting PEDs based on signal quality (e.g., signal strength) and this information may be used to determine travel configuration of the airplane during flight. The antenna 124 may be used for communication between the ground server 114 and the server 122. The ground server 114 may provide the server 122 with passenger information, or passenger manifest, prior to the departure of the flight. The ground server 114 may also provide additional information about passenger such as passenger's previous flight history or other social activities such that prior passenger engagements with IFE tracing can be performed.

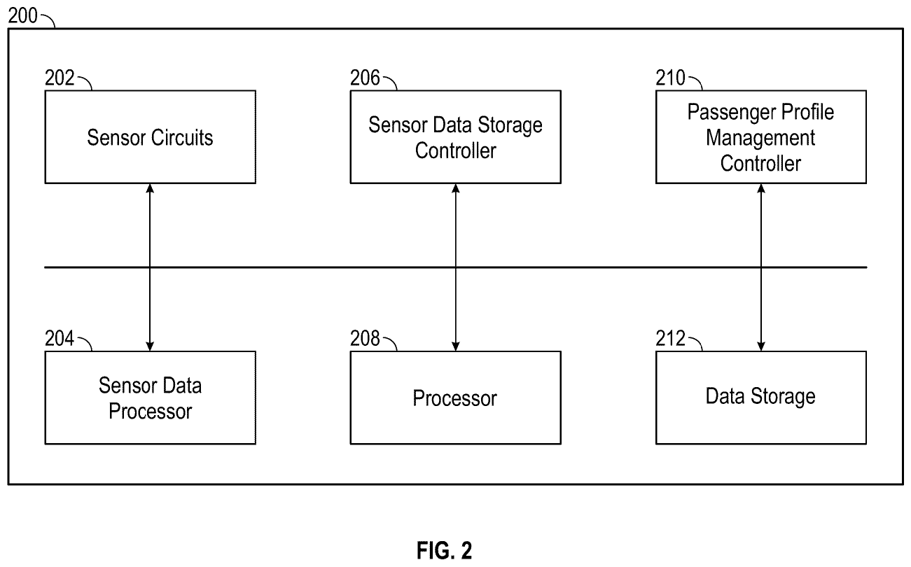

FIG. 2 shows an example of a system 200 for sensor data collection and analysis. The system 200 can include one or more sensor circuits 202, a sensor data processor 204, a sensor data storage controller 206, a processor 208, a passenger profile management controller 210, and data storage 212. In other embodiments, additional, fewer, and/or different elements may be used to configure the system 200. The data storage 212 may store instructions and applications to be executed by other components of the system 200, such as the processor 208. The data storage 212 can be an electronic holding place or storage for information or instructions so that the information or instructions can be accessed by, for example, the processor 208. The data storage 212 can include, but is not limited to, any type of random access memory (RAM), any type of read-only memory (ROM), any type of flash memory, such as magnetic storage devices (e.g., hard disk, floppy disk, magnetic strips, etc.), optical disks (e.g., compact disc (CD), digital versatile discs (DVD), etc.), smart cards, flash memory devices, etc. The instructions upon execution by the processor 208 configure the system 200 to perform the operations (e.g., the operations as shown in and described in this patent document). The instructions executed by the processor 201 may be carried out by a special purpose computer, logic circuits, or hardware circuits. The processor 208 may be implemented in hardware, firmware, software, or any combination thereof. The term “execution” is, for example, the process of running an application or the carrying out of the operation called for by an instruction. The instructions may be written using one or more programming language, scripting language, assembly language, etc. By executing the instruction, the processor 208 can perform the operations called for by that instruction.

The sensor data processor 204 and/or the processor 208 (e.g., CPU(s), GPU(s), HPU(s), etc.) can be a single processing unit or multiple processing units in a device or distributed across multiple devices. The processors 204, 208 can be operably coupled to the data storage 212 and/or other components of the system 200 with the use of, for example, a bus, such as a PCI bus or SCSI bus to receive, send, and/or process information and to control the operations of the system 200. The processors 204, 208 may retrieve a set of instructions from a permanent memory device, such as a ROM device, and copy the instructions in an executable form to a temporary memory device that is generally some form of RAM. In some implementations, the system 200 can include a plurality of processors that use the same or a different processing technology.

The sensor data storage controller 206 and/or the passenger profile management controller 210 of the system 200 can be configured to perform operations to assist the system 200. In some implementations, the controllers 206, 210 can be configured as a part of the processors 204, 208. When the system 200 communicates with the IFEC devices in FIG. 1, the controllers 206, 210 can be included in the airplane 102. In some implementations, the controllers 206, 210 can operate machine learning/artificial intelligence (AI) applications that perform various types of data analysis to automate analytical model building. Using algorithms that iteratively learn from data, machine learning applications can enable computers to learn without being explicitly programmed. The machine learning/AI module may be configured to use data learning algorithms to build models to interpret various data received from the various devices or components to detect, classify, and/or predict future outcomes. Such data learning algorithms may be associated with rule learning, artificial neural networks, inductive logic programming, and/or clustering. In some implementations, the controllers 206, 210 may assist the system 200 to perceive their environment and take actions that maximize the effectiveness of the operations performed by the system 200.

FIG. 3 shows an example of a rule-based system 300 for sensor data analysis. The system 300 can include a sensor network 302, a rule database 304, a passenger information database 306, one or more processors 308, and one or more I/O interfaces 310.

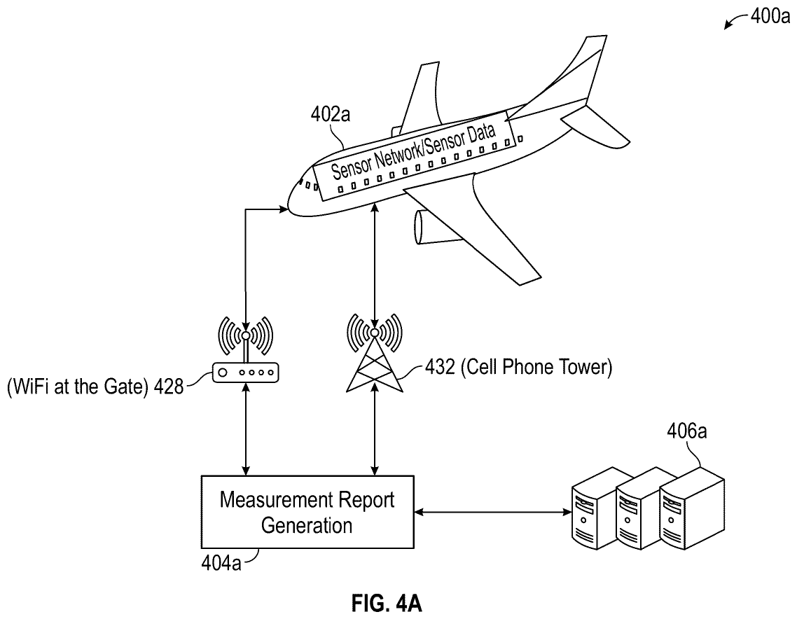

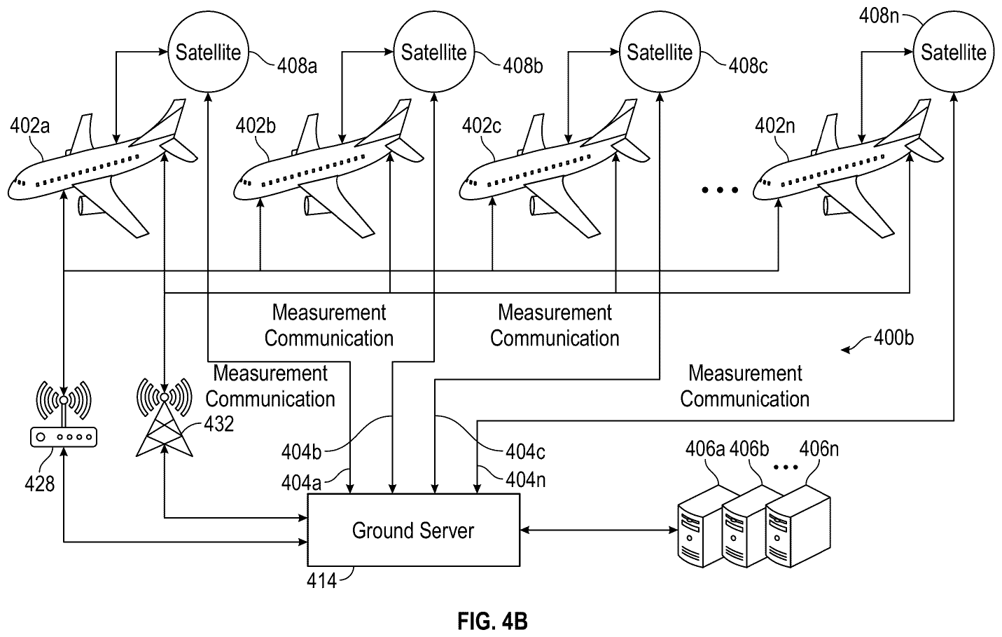

FIGS. 4A-4B show an exemplary system for sensor data gathering, processing and measurement report generation. In particular, FIGS. 4A and 4B shows a communication network in which sensor network 402a and sensor data may be collected and communicated to airplanes. A ground server 404 (which may operate similarly to the ground server 114) may be configured to communicate with airplanes 402a, 402b, . . . 402n either via a direct communication link or through a satellite connection using satellites 408a, 408b, 408c, . . . 408n. Databases 406a, 406b, . . . 406n may be used to store passenger information including sensor data that generates measurement report generation 404a, 404b, 404c, . . . 404n that creates/defines/pictorially represents passenger preferences, previous flight information, passengers usage information, e.g., IFE, airplane facilities, crew contacts, food and drink purchases, internet usage, products and services viewed, purchased, or saved to be purchased at a later time, etc. The ground server 404 may communicate passenger information including the prescreening information and/or the manifest information and/or boarding and/or deboarding (deplaning) information/plan to an airplane prior to take off. This information may be used by a server on the airplane to alert/adjust sensor network and which sensor data to collect more or less of during, for example, pre-flight, during flight, and end of as described in the present document. In some embodiments, the sensor data gathering, processing and measurement report generation system depicted in FIGS. 4A-4B may include equipment that provides wireless communication connectivity between the airplane equipment and ground based server via equipment 428 such as a Wi-Fi access point at the gate, or via a cellular communication equipment such as a cell phone tower 432 that may be available to the airplane at the airport or near gate area. As depicted in FIG. 4B, the Wi-Fi and cellular connectivity may also be available to some airplanes during flight.

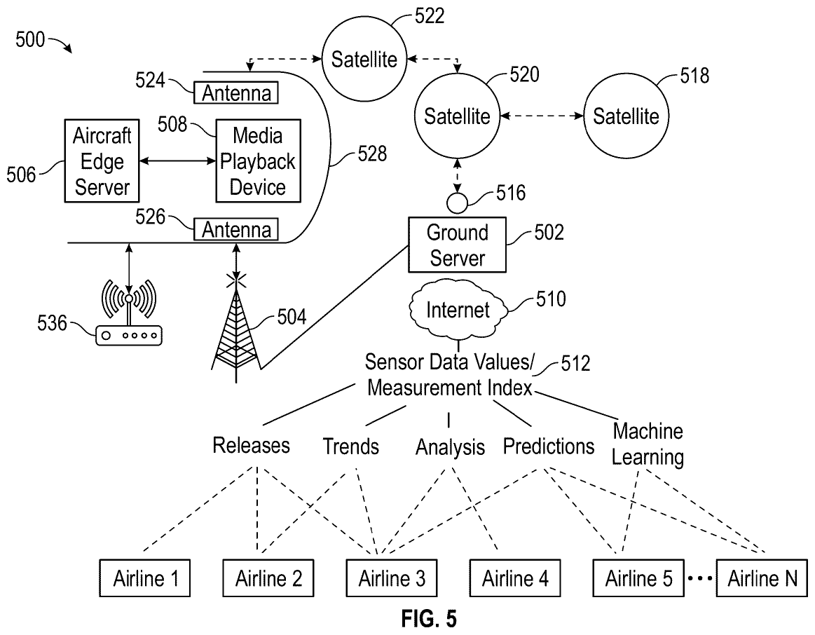

FIG. 5 shows another configuration of a system in which a ground server 502 may use information from multiple flights of multiple airlines (Airline 1, Airline 2 . . . Airline N). FIG. 5 shows another configuration of a system in which a ground server 502 may use information from multiple flights of multiple airlines (Airline 1, Airline 2 . . . Airline N). This information may be processed to, for example, establish trends in information based on sensor data at various previous locations where passengers were, predictions for upcoming flight of passengers in terms of sensor network recordings/reporting of likes and dislikes of passengers, and so on. In some embodiments, machine learning may be used to train a logic to perform trends (e.g., a measurement index) based on prior usage of sensor network and, for example, likes and dislikes and prior behavior/usage by passengers. Results of such analyses may be combined into the passenger information/plan 512 and stored at the ground server 502, possibly via communication through the internet 510. The ground server 502 may communicate the information via a satellite dish 516 with a network of satellites (518, 520, 522), which in turn is received in an airplane via antenna 524 by an onboard server (called edge server 506). The edge server 506 may implement the script described herein, along with providing media data to media playback devices onboard the airplane 528. Alternatively, or in addition, the ground server 502 may communication the information to the edge server 506 through a terrestrial connection such as through cellular communication via a cellular network 504 to a cellular reception antenna 526 onboard the airplane. The ground server 502 may be used, for example, to collect and distribute passenger information regarding watching 3^{rd} parties' products and services advertisements and specials. In some embodiments, the connectivity between the ground server 502 and airplane equipment may be based on a local area wireless network (e.g., a Wi-Fi access point 536) or a cellular communication network (e.g., cell tower 504) which may be available to the IFEC for communication while during a flight or when parked at an airport terminal, near the gate area.

### 3. Onboard Server Deployment Examples

An IFEC installation may include an onboard server that may be implemented in the form of one or more hardware platforms that include one or more processors, one or more computer memories and network interface for digital data communications. The onboard server may be configured to provide various instructions and content to the seatback displays, the wireless access points, Bluetooth transceivers and collect sensor data from the various onboard sensors. The onboard sensor may also be configured to communicate with a ground server or another server across the internet or a computing cloud for exchanging messages related to the rules to filter the sensor data, collect and transmit the sensor data, and so on. The onboard server may perform such communication in real-time (e.g., using the satellite communication path depicted in FIGS. 1 and 4B) or offline such as communicating with the ground sever at the end of a travel segment.

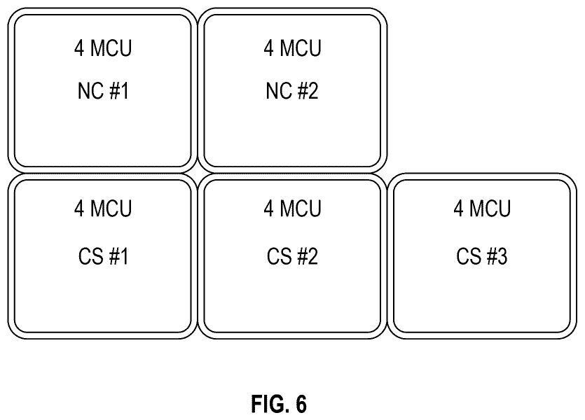

The onboard server 122 is sometimes called a headend that is deployed in the airplane. The headend functionality includes storing media data and providing the media data to the seatback displays, among others. One of the shortcoming of existing designs is that there typically is an imbalance in the symmetry of the networking, computational, and storage resources of each line replaceable unit (LRU). Additionally, in some implementations, at least three different blades or different LRUs may be needed to ensure high availability of software for in-flight experience. Furthermore, installation and field maintenance of existing systems can be cumbersome. For example, to change compute or storage resources on an airplane installation, the entire system, including chassis and other electronic blades (e.g., printed circuit boards) installed in an airplane may have to be swapped. Furthermore, airlines often carry different configurations of airplanes in their fleet, and present day systems require customized chassis according to type of aircraft. Furthermore, existing systems often carry redundant hardware in the chassis, in the form of backups, which require multiple separate power sources and other additional overheads. Furthermore, existing systems do not allow installation of a processor-only or a storage-only configuration. One example configuration is depicted in FIG. 6.

The techniques disclosed in the present document overcome, among other problems, the above-discussed shortcomings of the present day technology.

In some embodiments, a modular or scalable design may be used. The design may use upgradable compute & storage blade architecture in a standard chassis. For the design, a single form factor may be used that allows a flexible blade and back plane permutation. The design provides the ability to add additional boxes to accommodate a variety of configurations, redundancy, added storage, etc. The hardware platform may provide software cluster scalability, with options for redundancy (N-1, N-2). Each compute node (or compute blade) may be identical to the other.

The scalable design may accommodate expandable storage such as solid state memory (SSD) or another non-volatile memory. Furthermore, the design offers at least some level of backward compatibility (e.g., pin compatibility, or no re-wire required when replacing existing NEXT installations).

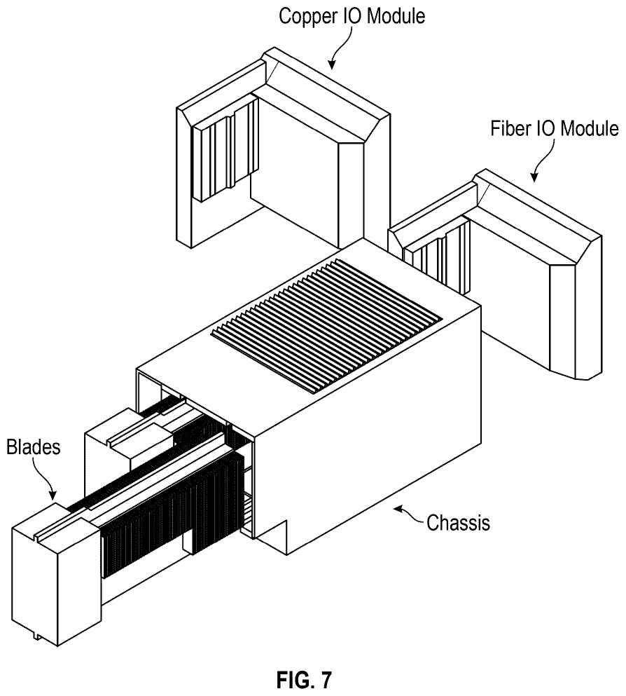

FIG. 7 shows an example of a proposed modular configuration. The configuration includes a chassis, further disclosed herein. The chassis is configured with slots that can accept blades. Each slot may be identical to each other. The physical dimensions of each blade may be identical, so regardless of the functionality, each blade may have the same physical dimensions, allowing it to be placed in any slot. The configuration depicted in FIG. 7A allows for 2 blades to be added to the chassis. The chassis may further include one or more receptacles for network interface or input-output (I/O) modules. For example, one I/O module may have a copper interface such as ethernet. Another I/O module may have a fiber interface. The modules may be designed to have identical physical characteristics, so they can be plugged into a same receptacle form factor, thereby providing a decided connectivity to the configuration.

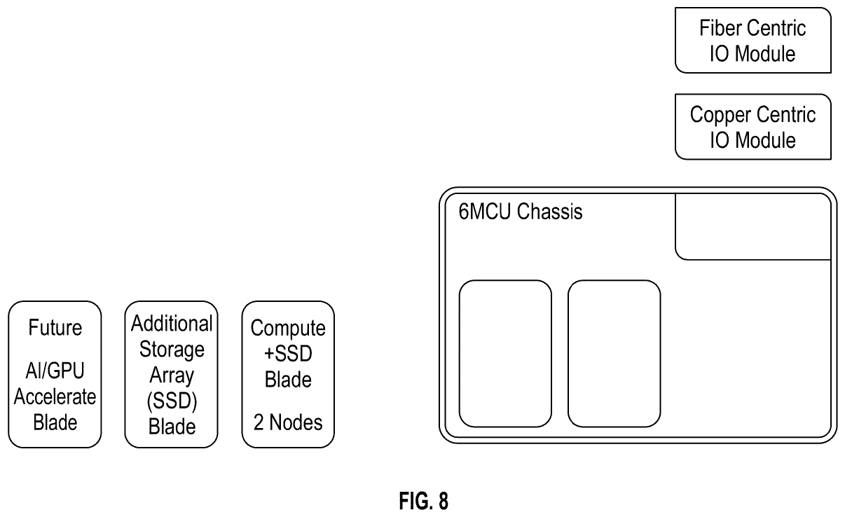

FIG. 8 shows an example of a chassis having a size of 6 LRU units. The chassis may allow a total 6 modules to be inserted, including zero or more compute blades, zero or more storage blades (e.g., SSD blades), zero or more accelerators for tasks such as machine learning/artificial intelligence based computations or graphics tasks, and alternate computing platforms. As previously disclosed, I/O modules may be copper, fiber and the like interfaces.

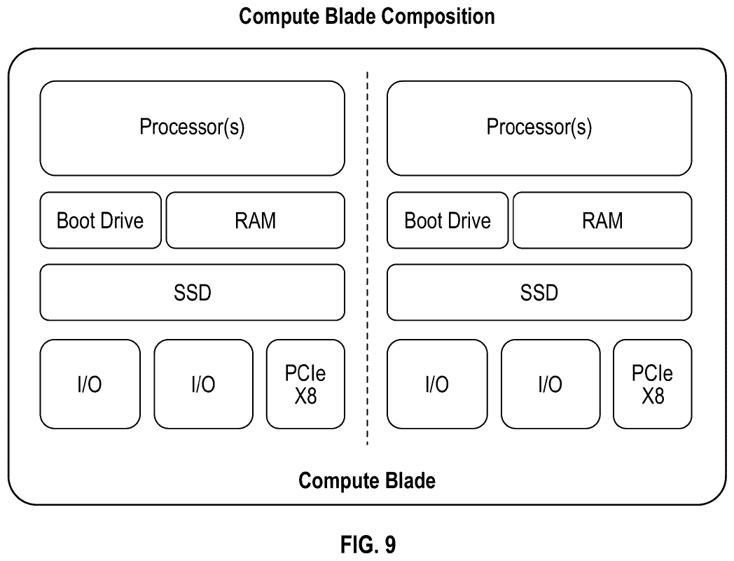

FIG. 9 shows an example compute blade configuration. Here, two identical modules are included on the same blade. Each module includes one or more processors. Each module includes a boot drive and/or a random access memory (RAM). Each module may include bulk data storage such as 32 or 64 gigabyte SSD. Each module may include dual input input-output modules such as 1 or 10 Gigabit ethernet module for communication with external entities and a bus interface such as PCIe interface.

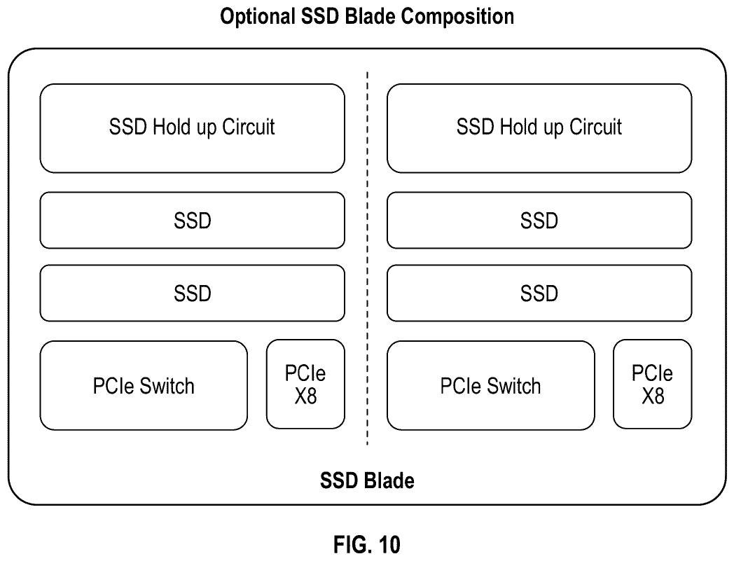

FIG. 10 shows an example storage blade configuration. The storage blade may include two identical or different units that include one or more storage units such as SSDs, a corresponding SSD hold up circuit to control access and interfaces such as PCI or PCIe interfaces.

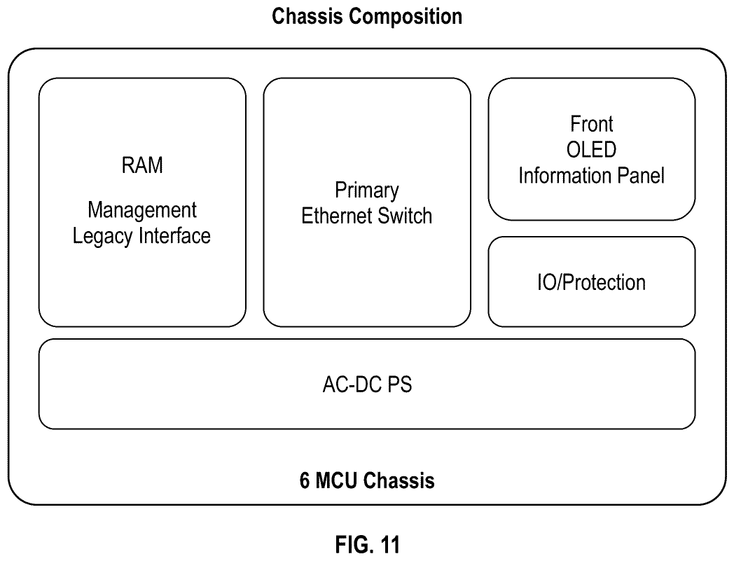

FIG. 11 shows an example of a chassis embodiment. As depicted, the chassis may include one or more of the following: (1) a primary switch (e.g., an ethernet switch) that allows cross-connectivity among blades, (2) a user interface such as an organic light emitting diode (OLED) panel for display of chassis information and receiving user inputs, (3) a memory and/or a processor to support a legacy interface, allowing legacy interfaces to be used with new chassis.

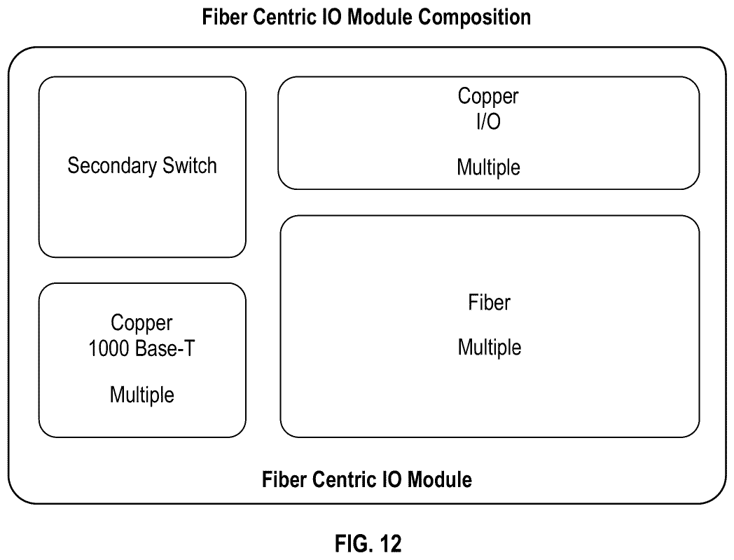

FIG. 12 shows an example of a fiber specific input output module. The module may be made pin-compatible with existing server chassis, and may include two separately operating ethernet switches to such that additional ports can be created. The module may include a fiber transceiver, and may include a number of copper ports for ethernet transmission.

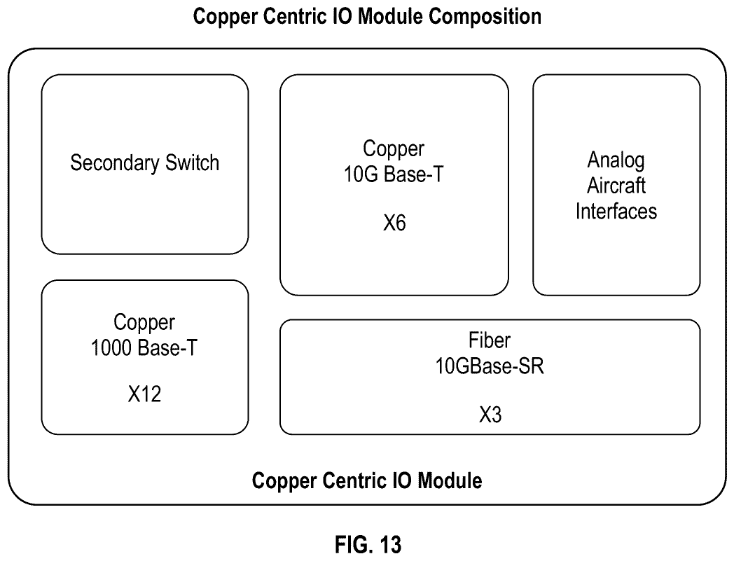

FIG. 13 is an example of a copper centric input output module. The module may be made pin-compatible with existing server chassis, and may include two separately operating ethernet switches to such that additional ports can be created. The module may include a fiber transceiver, and may include a number of copper ports for gigabit ethernet transmission. The module may include legacy (e.g., analog) aircraft interfaces such as IS equivalent, audio and Arinc 429 interface.

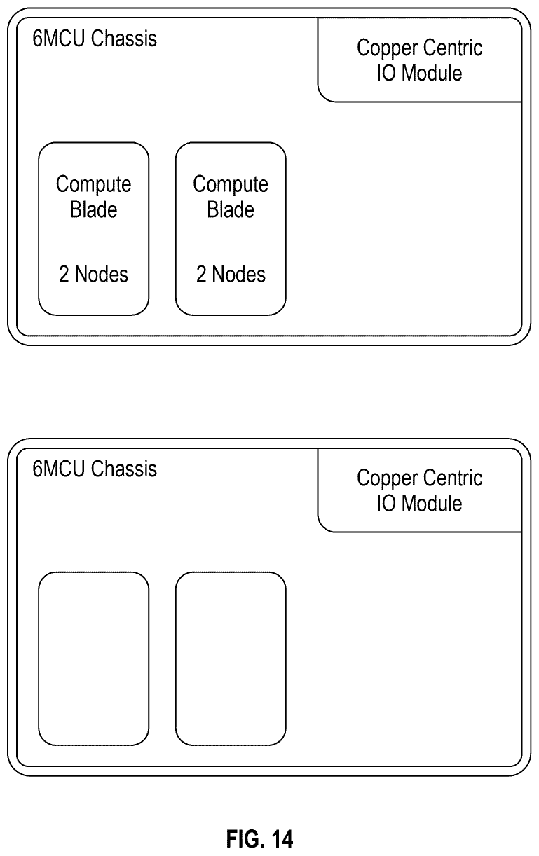

FIG. 14 is an example of an onboard server (top) and a legacy interface server (bottom). For the onboard server, a copper I/O module is show with two compute blades. Because the legacy interface is implemented by the chassis processor, no blades are inserted in the slots for the legacy interface server, which is shown to have a copper I/O module.

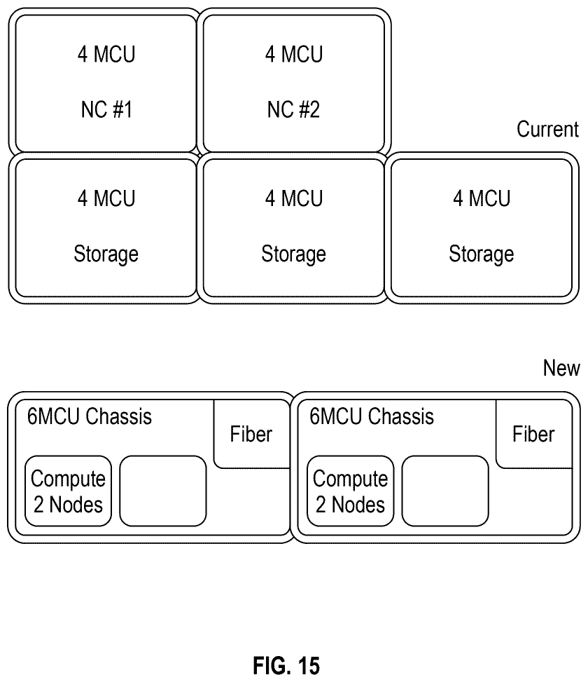

FIG. 15 shows an example of a system implementation to compare the efficiencies achieved by some embodiments. Top shows an example current configuration of an inflight server, showing two network cards and three storage blades. The same functionality (and more) is achieved using the new design using two blades, each of which has two compute nodes on a single blade. The other slot can be left empty (e.g., a dummy module is used), thereby providing power and cooling advantage.

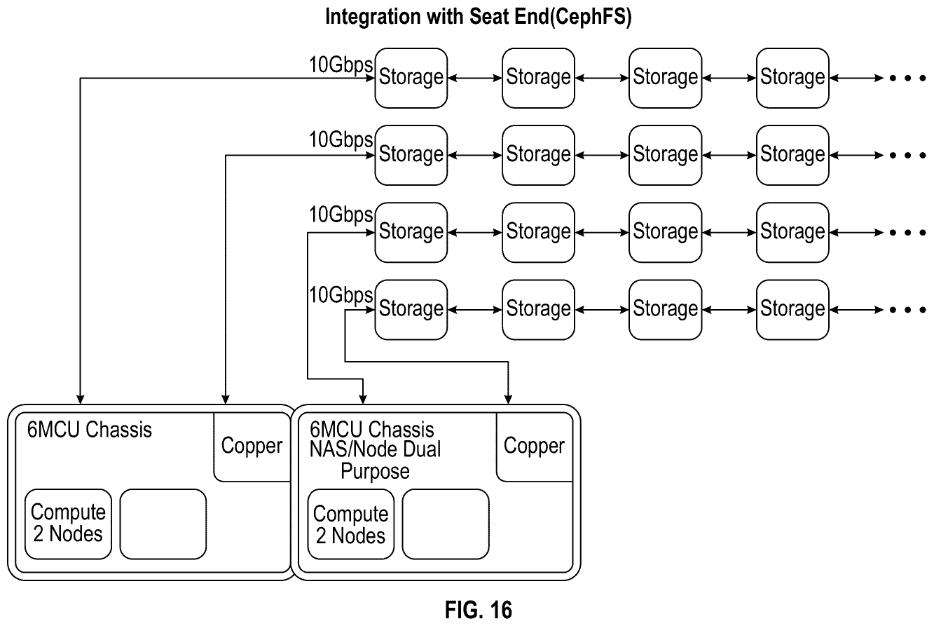

FIG. 16 shows an example of integration of the modular server with electronics associated with seats in the aircraft. Here, an example of a 10 Gbps connection with rows of seats is shown, with each seat row having some number of storage units for storing content.

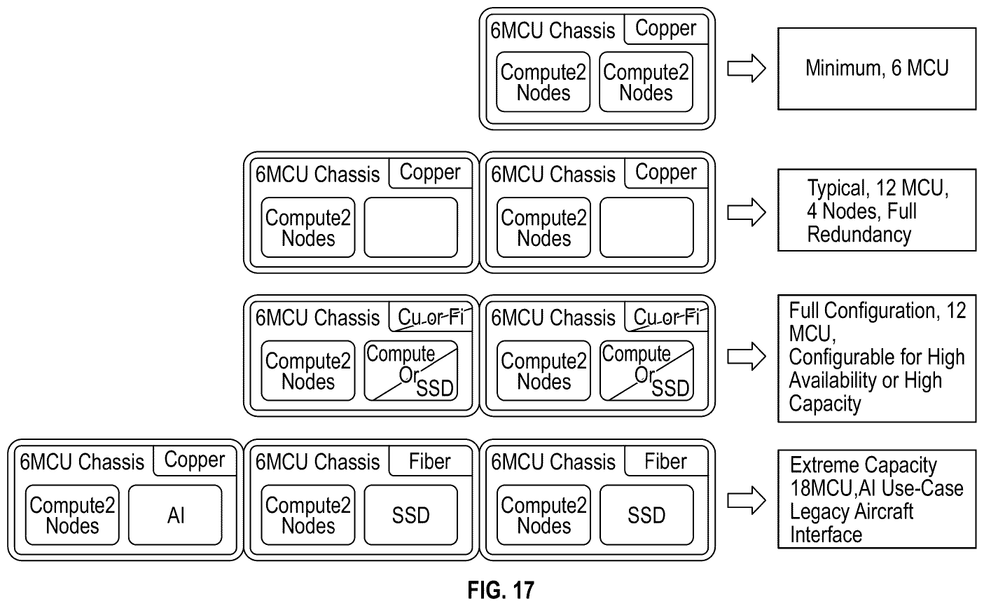

FIG. 17 shows some examples of configurations possible with the modular server architecture. From top to bottom, generally, the number of modules used, the amount of electronics used and the type of functionality offered increases.

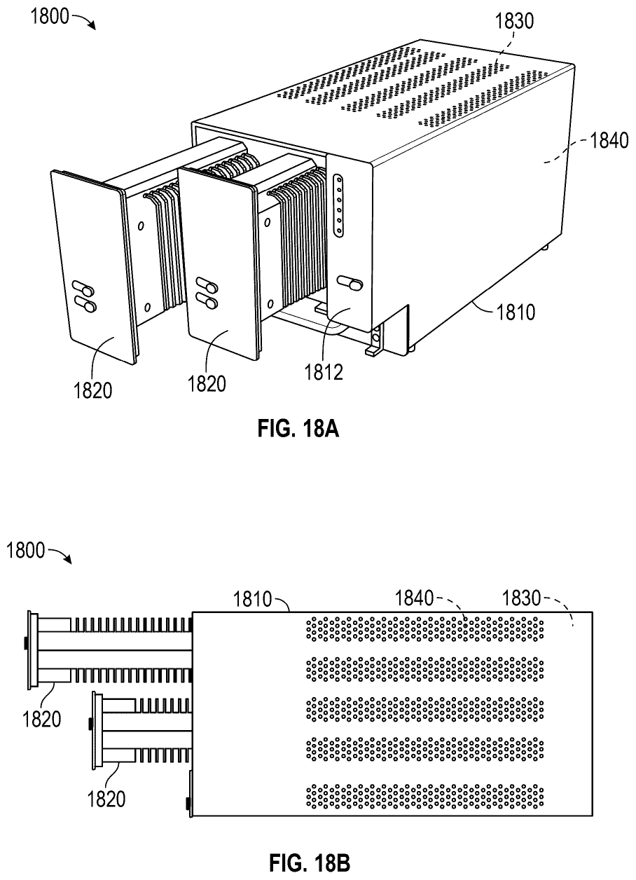

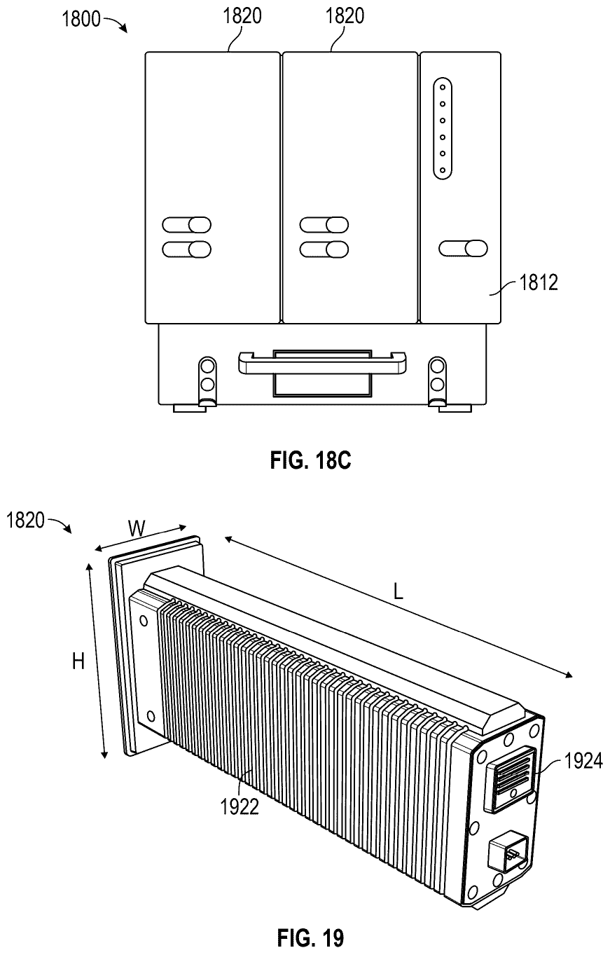

FIGS. 18A-18C are front perspective, top, and front views, respectively, of an aircraft server 1800 configured in accordance with various embodiments of the present technology. Referring to FIGS. 18A-18C together, the server 1800 can include a chassis 1810, a pair of modules 1820, an I/O interface module 1830 (obscured from view), and a power supply 1840 (obscured from view). The chassis 1810 can have a generally rectangular form factor and can house the pair of modules 1820. The dimensions of the chassis 1810 can be about 379 mm×190 mm×194 mm. The chassis 1810 can meet a 6 Modular Concept Unit (MCU) size requirement. The chassis 1810 can include an interface panel 1812 configured to communicate various operating parameters of the server 1800. For example, the interface panel 1812 can indicate (e.g., via labels and corresponding lights) whether power is on, whether the server 1800 is connected to a network, whether the server 1800 is properly connected to a controller, whether either or both of the pair of modules 1820 are connected, and/or the like.

Each of the I/O interface module 1830 and the power supply 1840 can be housed in the chassis 1810. The I/O interface module 1830 can be a copper I/O module, a fiber I/O module, and/or the like. In some embodiments, the I/O interface module 1830 is fixedly secured in the chassis 1810 and, accordingly, unlike the server illustrated in FIG. 7, not swappable for a different I/O interface module. The pair of modules 1820 can be individually inserted into or pulled out of the chassis 1810. For example, the modules 1820 can be mounted on rails coupled to the chassis 1810 for easy access. The modules 1820 are described in greater detail below with reference to FIG. 19. The server 1800 can weigh between about 11-25 lbs. In some embodiments, each server 1800 can include one or more storage blades supporting storage between about 32-96 TB, and/or one or more compute blades supporting 32 cores and 64 threads (e.g., each module 1820 can support or have 16 cores and 32 threads). The blades can also be AI accelerators, non-volatile storage devices, volatile storage devices, and/or the like. Modules 1820 having different types of blades can be mixed-use modules (e.g., mixed-use peripheral modules).

FIG. 19 is a rear perspective view of one of the modules 1820. As shown, the module 1820 can include a plurality of slots 1922 for receiving compute blades (e.g., the blades illustrated in FIGS. 8-10) and an I/O interface 1924 at the rear end. The pair of modules 1820 can receive the same set or different sets of compute blades as one another. The I/O interface 1924 can be operably coupled to the I/O interface module 1830 within the chassis 1810 (e.g., via a wired connection). In some embodiments, the module 1820 has a height H between 100-200 mm (e.g., 143 mm), a width W between 50-100 mm (e.g., 74 mm), and a length L between 100-500 mm (e.g., 310 mm). Each module 1820 can weigh between about 5-7 lbs.

The module 1820 allows forward compatibility to support compute module from 2 to N nodes. The module 1820 can scale up to N discrete processing nodes and can access a unified and distributed resources on the LRU. The compute node can hold up to N nodes of processor modules. Each node can employ distributed storage methods to provide a highly available replicated storage system. This topology software can create software-defined storage pools for use in their applications, with each module being highly available. In some embodiments, the server 1800 further includes one or more thermal sensors and/or airflow sensors to allow software to scale each node's power usage to conform to the aircraft's thermal requirements.

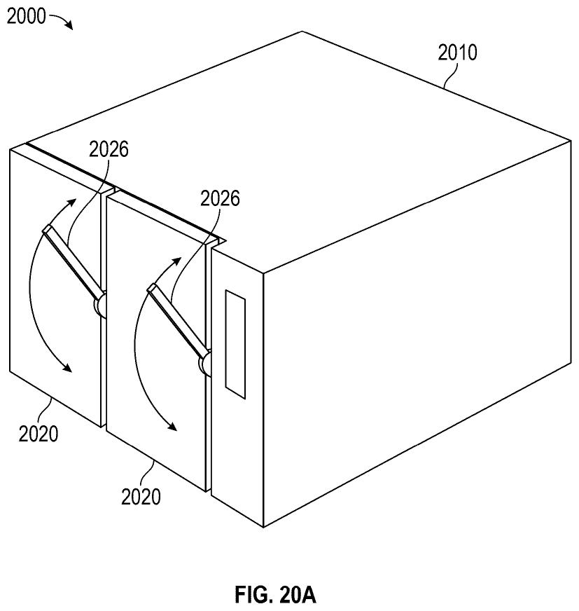

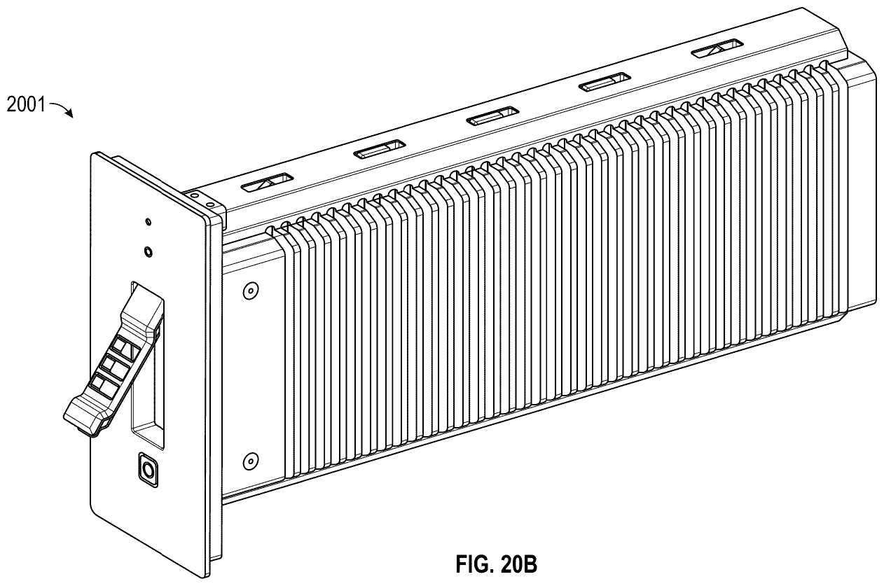

FIG. 20A is a perspective view of another aircraft server 2000 configured in accordance with various embodiments of the present technology. As shown, the server 2000 can include a chassis 2010 and a pair of modules 2020. Each module 2020 can include a latch 2026 at the front side. The latch 2026 can be pivoted between (i) a locked position in which the corresponding module 2020 cannot be pulled out of the chassis 2010 and (ii) an unlocked position in which the corresponding module 2020 can be pulled out of the chassis 2010. The locked and unlocked positions can correspond to when the latch 2026 is rotated down and up, respectively, or vice versa. Thus, an operator can access the slots of the modules 2020 for adding or removing electronic blades to and from without the use of a separate tool. The electronic blades may comprise compute blades that are particularly designed to offer computing resources and/or storage blades that are designed to offer data storage capabilities.

FIG. 20B is a perspective view of a server module 2001 including a latch and configured in accordance with various embodiments of the present technology. The latch can function in a similar manner as described above with respect to the latch 2026.

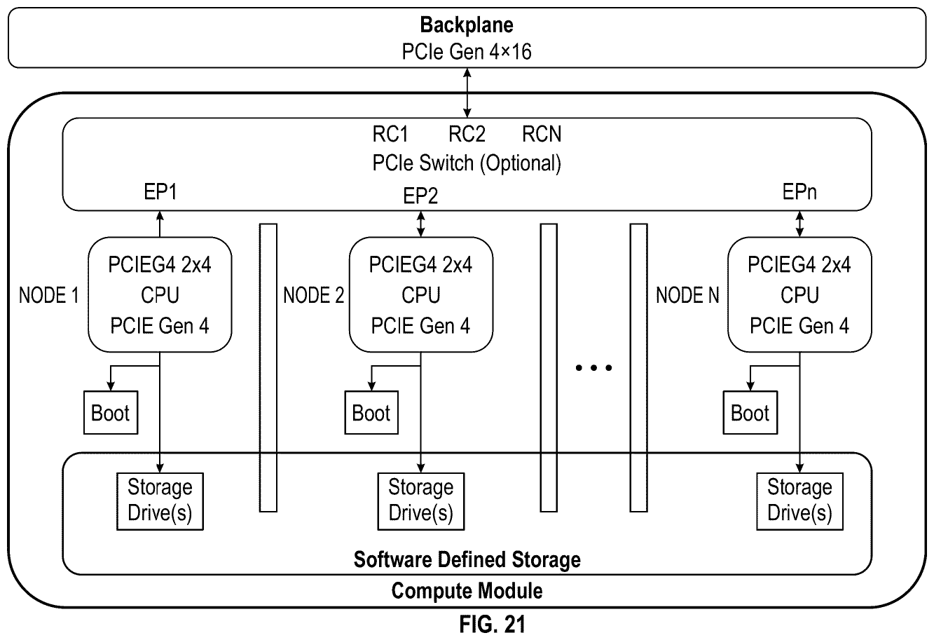

FIG. 21 illustrates multi-processor sub-systems with software defined storage and configured in accordance with various embodiments of the present technology. A compute node can hold up to N nodes of processor modules. Each node can have storage that can be combined using distributed storage methods to provide a highly available replicated storage system. With this topology software, the server can create software-defined storage pools for use in applications, with each module being highly available. Thermal sensors and airflow sensors can be provided to allow the software to scale each node's power usage to conform to the aircraft's thermal requirements, as discussed in further detail herein. An optional PCIe switch can be used for two or more CPU subsystems to allow the possibility of multi-host sharing of PCIe endpoint devices such as NVMe storage drives and GPU/AI accelerators. Via the 2-slot chassis, more compute/storage subsystems can be added on the second slot for higher application scalability. In addition to the on-board storage pool, the compute module can offer PCIe expansion to a secondary module to provide additional storage to increase its storage pool size or to GPU/AI resources.

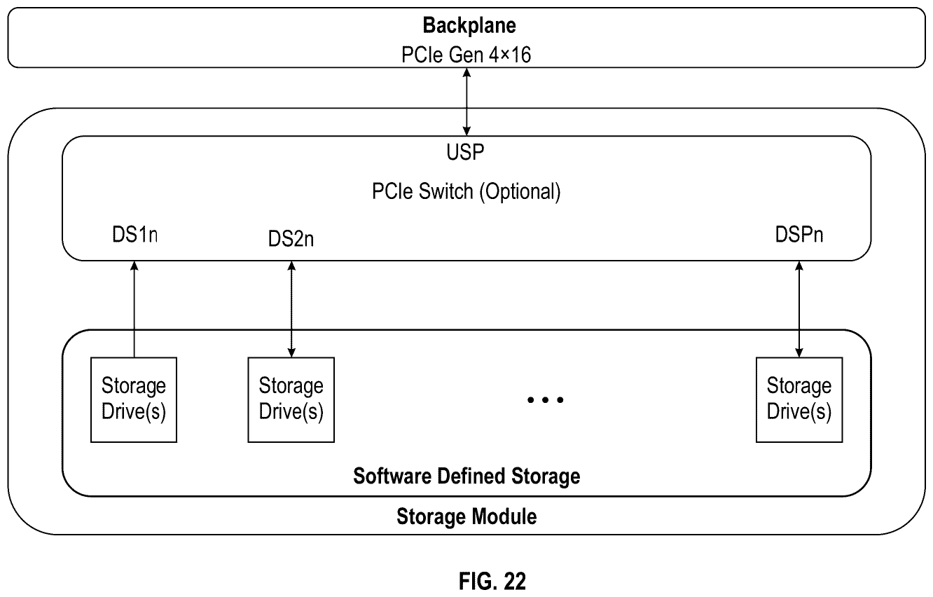

FIG. 22 illustrates the storage expansion ability of servers configured in accordance with various embodiments of the present technology. By including the 2-slot chassis, the server can have the ability to expand with additional NVMe storage to the subsystem via additional PCIe lanes on the backplane. The multi-processor module can be used in slot 1, and a storage module can be used in slot 2.

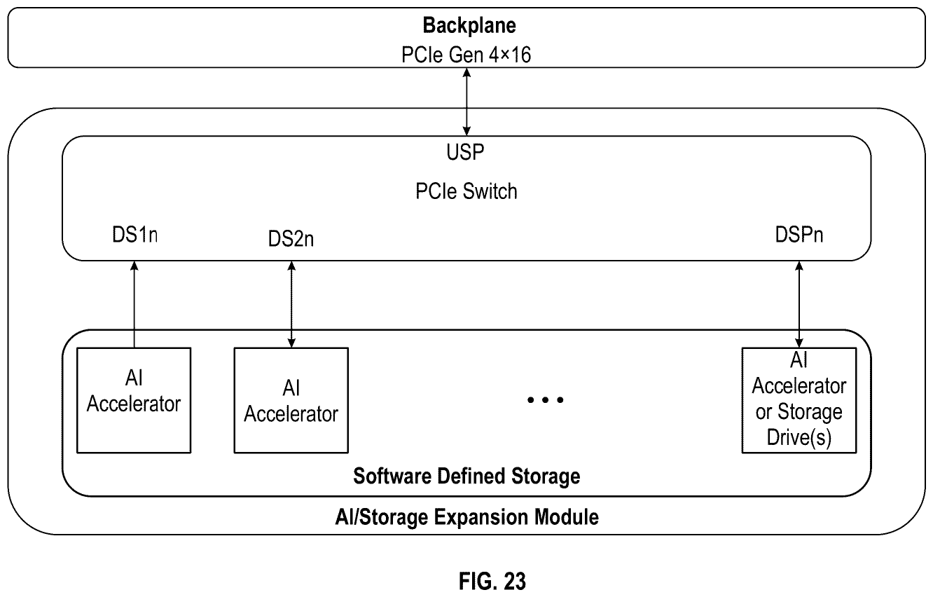

FIG. 23 illustrates PCIe GPU/AI accelerators and mixed use abilities in accordance with various embodiments of the present technology. Given the nature of the backplane being PCIe, the expansion module could provide more than just storage. A mixed-use case can be made that supports AI acceleration, GPU compute, and/or additional storage.

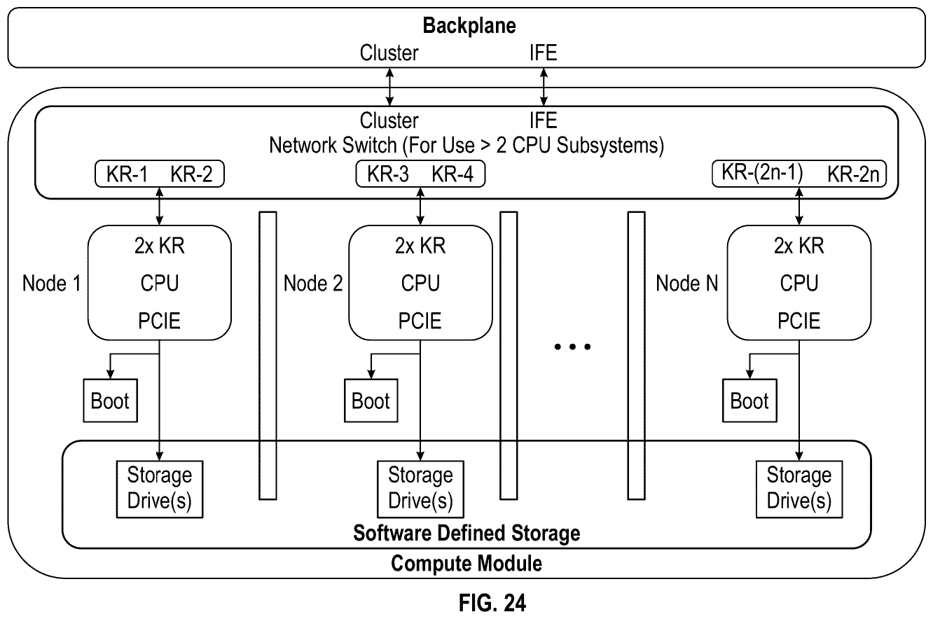

FIG. 24 illustrates multi-processor subsystems with cluster and IFE networking in accordance with various embodiments of the present technology. Each compute module with N processing sub-systems can connect to a network utilizing a cluster and public networking scheme to allow for performance improvement. The cluster network can include a private network that may network traffic only for headend cluster-related use. The public network may used for all other IFE traffic.

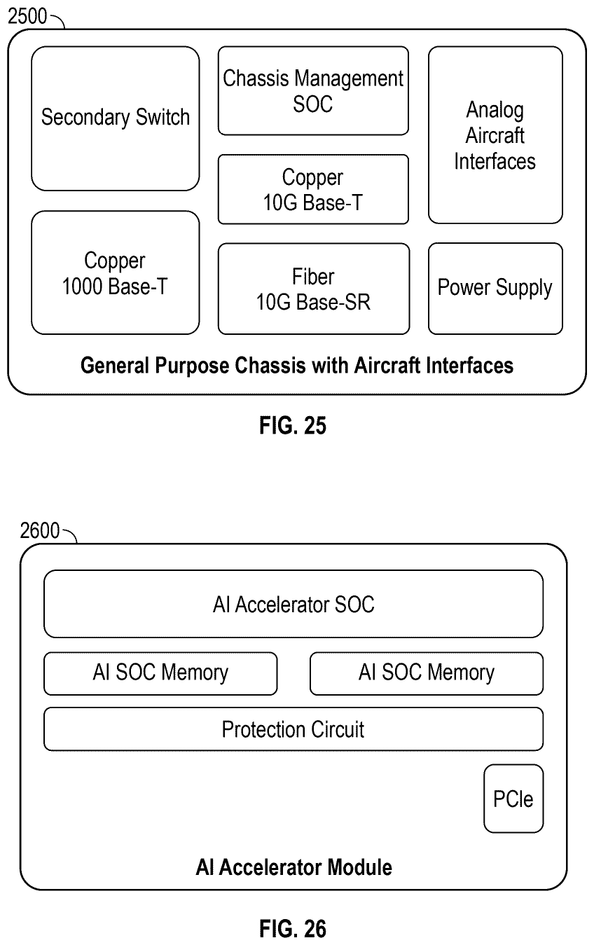

FIG. 25 is a schematic diagram of a server chassis 2500 configured in accordance with various embodiments of the present technology. As shown, the chassis 2500 can house copper and fiber network interfaces, an integrated network switch, aircraft interface connections, a power supply, and a dedicated System-on-Chip (SoC) for chassis management. This configuration can streamline functionality, enhance redundancy, and optimize space utilization within the aircraft server infrastructure. With the chassis 2500 providing the necessary infrastructure and standardized hardware connections, core server functions such as content serving, gaming, and map services can be offloaded to dedicated modules. Since each module no longer requires its own AC power supply converter, network switch, or other redundant components, it can achieve greater space and power efficiency. Thus, each module can be optimized to include only the essential functional circuits, such as CPU, storage, GPU, or AI processing units. Example compute and storage modules are illustrated in and described above with reference to FIGS. 9 and 10, respectively.

FIG. 26 is a schematic diagram of an artificial intelligence (AI) accelerator module 2600 configured in accordance with various embodiments of the present technology. The AI accelerator module 2600 can be designed as a direct-attached peripheral to the general-purpose compute module (e.g., FIG. 9), enhancing AI processing efficiency. The module 2600 is focused solely on the AI Accelerator SoC and its essential support circuits, allowing it to fully leverage the available power and space within the module 2600. As a result, it maximizes utilization efficiency by concentrating resources on the AI tasks at hand.

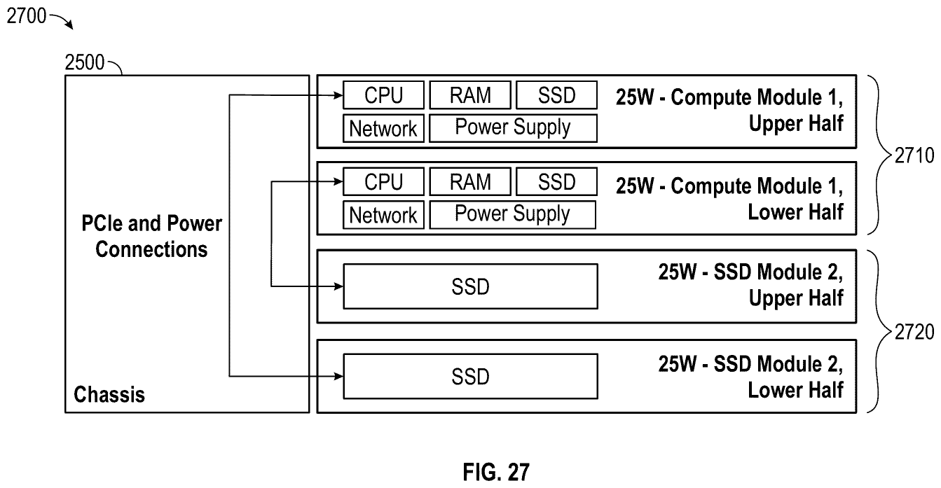

FIG. 27 is a schematic diagram illustrating connectivity within a server 2700 configured in accordance with various embodiments of the present technology. As shown, the server 2700 can include the chassis 2500 (FIG. 25) and a pair of modules include a compute module 2710 and a storage module 2720. As discussed above, each module can include two units. Thus, for illustrative purposes, each of the compute module 2710 and the storage module 2720 is illustrated as two components: an upper half and a lower half (each half is also referred to herein as “a complex”). Further as shown, the upper half of the compute module 2710 can directly communicate with the lower half of the storage module 2720, and the lower half of the compute module 2710 can directly communicate with the upper half of the storage module 2720. The communications can be performed via, for example, PCIe connections or interfaces within the chassis 2500 (e.g., a dedicated PCIe peripheral bus for direct peripheral connections). The server 2700 can also support ethernet-based cross-module communication. This is in contrast to many existing server configurations in which the chassis may include a network switch, and the individual modules must communicate with one another through the network switch of the chassis.

Server configurations of the present technology focus on achieving shared infrastructure and direct-attached functionality to optimize space, power, and efficiency for aircraft applications. For example, if each module were to have its own processor and support infrastructure, the total power consumption of the server chassis 2500 would exceed the aircraft rack's power requirements significantly. In particular, the illustrated embodiment can allow the full 50 W power allocation for the second slot of the chassis 2500 to be used entirely by the storage modules 2720, each of which only includes a SSD-25 W per set of SSDs for each compute complex-enabling a much larger SSD array to be implemented efficiently.

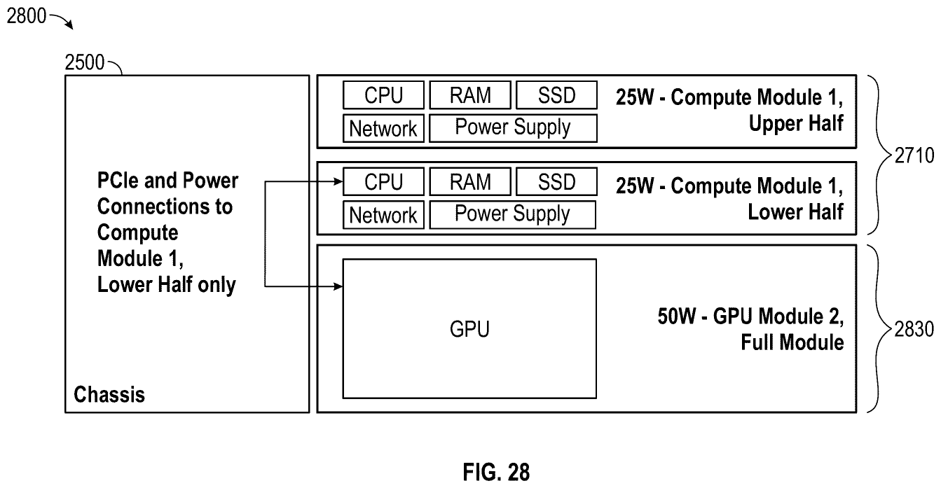

FIG. 28 is a schematic diagram illustrating connectivity within another server 2800 configured in accordance with various embodiments of the present technology. The server 2800 can be generally similar to the server 2700 of FIG. 27, and includes the chassis 2500 and the compute module 2710. Instead of the storage module 2720, however, the server 2800 can include a GPU module 2830. Unlike the compute module 2710 and the storage module 2720, which can be a symmetrical dual-complexes, the GPU module 2830 can be an asymmetrical single-complex. Thus, the GPU module 2830 is allowed to utilize the entire 50 W power allocation and the full volume of the module as a dedicated peripheral for one of the compute complexes. This flexibility enables the use of higher-power peripherals, rather than always splitting the 50 W power allocation symmetrically between each compute complex, making it possible to support more power-intensive components. It is appreciated that in other embodiments, other modules, such as the AI accelerator module 2600 of FIG. 26 can be included.

Referring to FIGS. 7-28 together, embodiments of the present technology are expected to offer greater compute and storage capabilities while occupying less volume within the aircraft. In addition to increased performance and reduced size, the headend servers disclosed herein are modular, allowing operators to swap (e.g., hot swap) blades depending on the specific needs of the aircraft system. The headend servers are also compatible with most, if not all, aircraft types and aircraft networks (e.g., by offering copper or fiber I/O interface modules). The modules also provide internal redundancy of storage, reducing the need for extra servers. The headend servers can also be forward compatible, allowing operators to include new types of blades or nodes in the future as needed. By offering forward compatibility, the headend servers disclosed herein can standardize aircraft installations for future advancements in commercial aviation.

### 4. Select Embodiments of Blades and Operations Management within Server Chassis

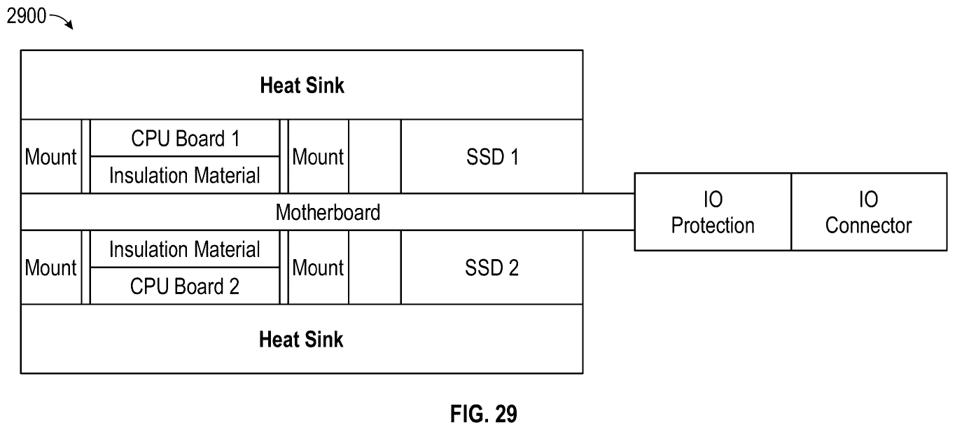

FIG. 29 is a cross-sectional view of a server module 2900 configured in accordance with various embodiments of the present technology. The server module 2900 can include a motherboard, a pair of CPU boards, a pair of insulating materials, a pair of heat sinks, mounts, a pair of SSDs, an I/O protection unit, and an I/O connector. In many existing modules, only one of each of a CPU board, a heat sink, and an SSD is attached to the motherboard. In contrast, the server module 2900 of the present technology includes pairs positioned on opposite sides of the motherboard. In particular, the CPU boards are positioned on either side of the motherboard, the insulating materials are disposed between corresponding ones of the CPU boards, the heat sinks are positioned on the sides of the CPU boards opposite the motherboard, and the mounts can support the heat sinks. Moreover, the SSDs can be coupled to either side of the motherboard and spaced apart from the CPU boards (e.g., along the length of the motherboard). The I/O protection unit and the I/O connector can be connected to a distal end of the motherboard.

The central motherboard serves not only as a PCB to route all required signals from the compute modules to the connectors but also as a shared mechanical structure for mounting the heatsinks, module housing, and other components. This design provides the necessary structural reinforcement for the two compute complexes while occupying only the space and thickness of a single PCB. In operation, as the CPU boards heat up, heat dissipation is directed in opposite directions away from the motherboard due to the relative positions of the corresponding heat sinks. The insulation materials and/or the fiberglass in the motherboard PCB can further significantly reduce thermal interference between the CPU boards.

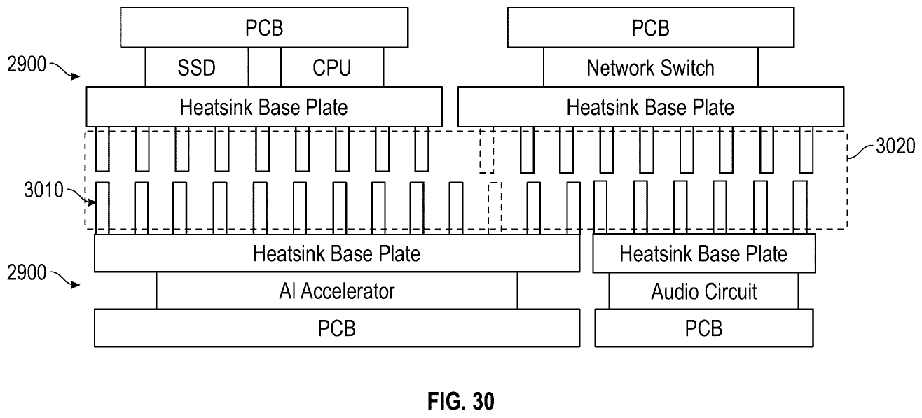

FIG. 30 is a schematic top view of adjacent server modules 2900, illustrating thermal management in accordance with various embodiments of the present technology. In many existing server thermal management systems, server components are distributed within the cross-section of an air tunnel. This conventional airflow design, however, has limitations in aircraft server use cases. The boundary of the air tunnel, which is typically constructed from materials, can add significant weight overhead. Additionally, the PCB must be placed in the airflow path, which introduces extra resistance due to its cross-sectional area and the roughness caused by mounted components. These factors can negatively impact airflow efficiency (e.g., create turbulent flow) and contribute to overall system weight.

As shown, adjacent server modules 2900 can be spaced apart from one another, and a plurality of heatsink fins 3010 can be positioned to extend along the height of the modules 2900 (e.g., into the page) and extend from one of the modules 2900 towards the other. In some embodiments, the heatsink fins 3010 are in thermal contact with corresponding ones of the modules 2900 and are thermally conductive. For example, the heatsink fins 3010 can be made of a metal (e.g., copper) or other thermally conductive, suitable material such that the heatsink fins 3010 can direct the heat dissipated through the heatsinks to the gap between the modules 2900. The gap can define an air tunnel 3020 in which, as discussed in further detail herein, air can flow to further dissipate heat. In some embodiments, the heatsink fins 3010 can help maintain laminar flow through the air tunnel boundary 3020.

The illustrated configuration can eliminate the need for additional materials to construct the air tunnel 3020, as the heatsinks already have integrated base plates. More importantly, the airflow path now only contains the heatsink fins, which are optimized for airflow, while the high-resistance PCB, with its parts and mounting points, is no longer in the airflow path. This innovation significantly improves airflow efficiency by reducing air resistance and optimizing heat dissipation.

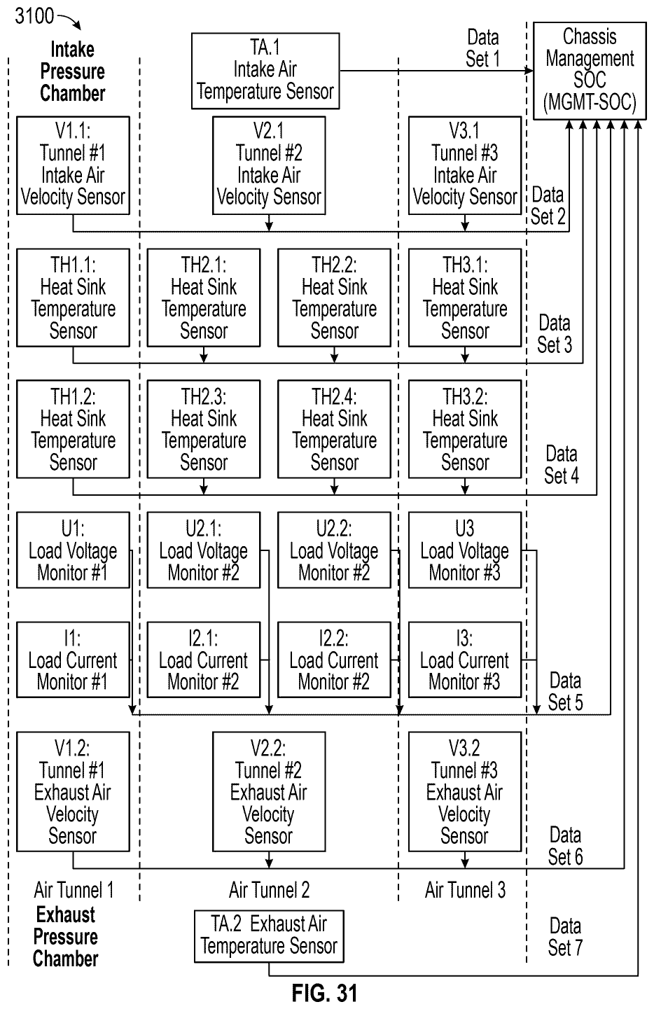

FIG. 31 is a schematic diagram illustrating an operations management system 3100 (“the system 3100”) of a server on an aircraft, configured in accordance with various embodiments of the present technology. As previously discussed, servers of the present technology can include two modules housed within a chassis. Thus, when the two modules are positioned parallel to one another, the chassis and the modules can define a first air tunnel between a left wall of the chassis and a first module, a second air tunnel between the first module and a second module, and a third air tunnel between the second module and a right wall of the chassis, labeled “Air Tunnel 1,” “Air Tunnel 2,” and “Air Tunnel 3,” respectively. The three air tunnels can share an intake pressure chamber and an exhaust pressure chamber at opposite ends. As shown in FIG. 31, the system 3100 can include a plurality of sensors, monitors, and/or the like strategically positioned, not only between the three air tunnels, but also along the lengths of the air tunnels, as discussed in further detail herein. Also as described in further detail herein, the system 3100 can monitor power consumption, thermal loads, and/or other operation “health” statuses of the server (e.g., the server 2700, 2800 of FIGS. 27 and 28).

In the illustrated embodiment, the system 3100 includes an intake air temperature sensor, an intake air velocity sensor for each air tunnel, a plurality of heat sink temperature sensors, a plurality of load voltage monitors, a plurality of load current monitors, an exhaust air velocity sensor for each air tunnel, and an exhaust air temperature sensor. Thus, the sensors of the system 3100 can measure and collect data regarding power consumption, IC temperatures, intake air temperatures, exhaust air temperatures, air flow, heatsink temperatures, core components' voltage and current loads, etc. The sensor measurement outputs can be communicated to the chassis management SOC.

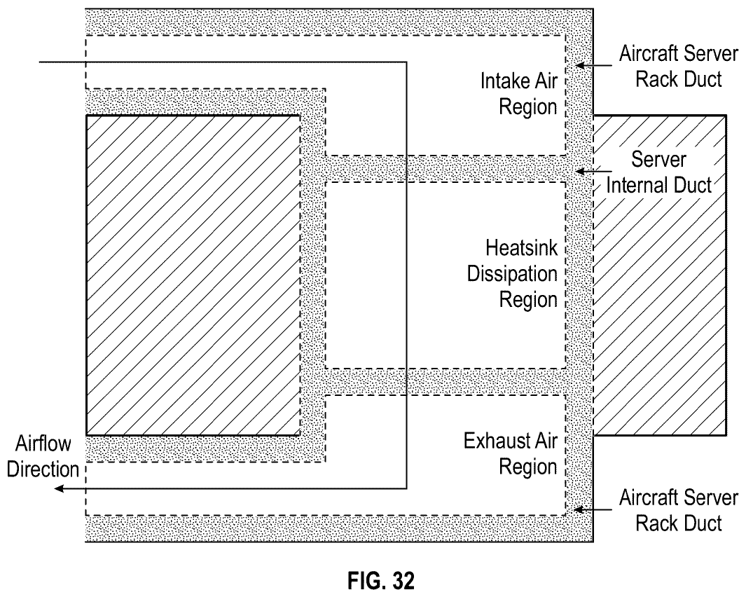

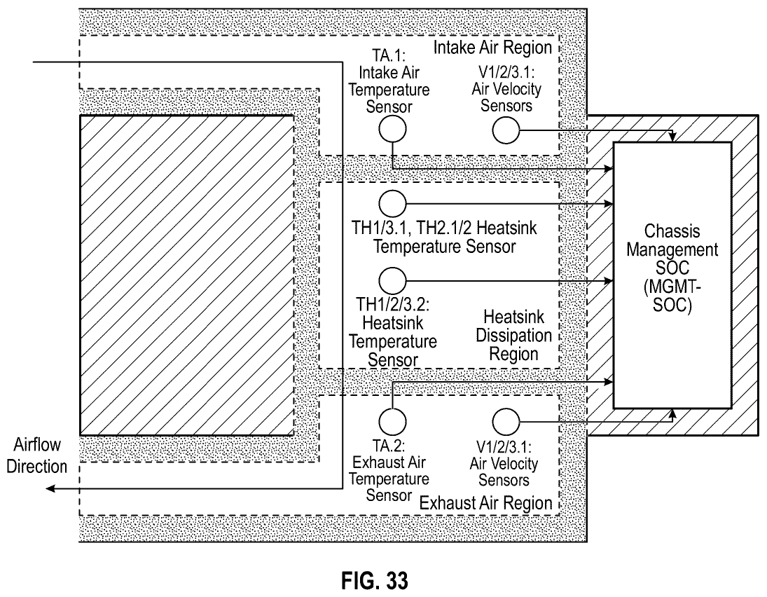

FIGS. 32 and 33 are schematic cross-sectional side views of the server. Referring first to FIG. 32, airflow can flow from a first end, down through ducts of the server rack and/or the server internal ducts, and out through a second end. In particular, the airflow can flow past an intake air region, a heatsink dissipation region, and an exhaust air region.

Referring next to FIG. 33, the positions of the sensors illustrated in FIG. 31 are shown relative to the server. In particular, the intake air temperature sensor and the intake air velocity sensors (e.g., one for each air tunnel) can be positioned in the intake air region. The heatsink temperature sensors can be positioned in the heatsink dissipation region. The exhaust air temperature sensor and the exhaust air velocity sensors (e.g., one for each air tunnel) can be positioned in the exhaust air region. Furthermore, each of the sensors can be operably coupled to the chassis management SOC.

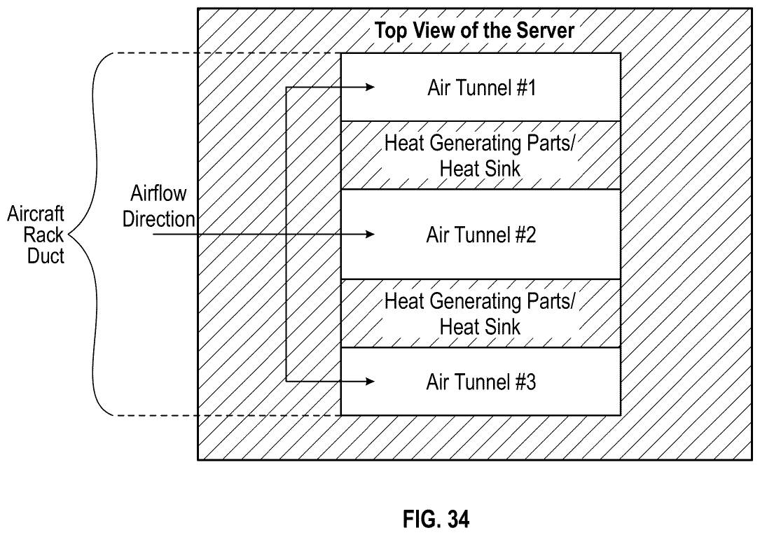

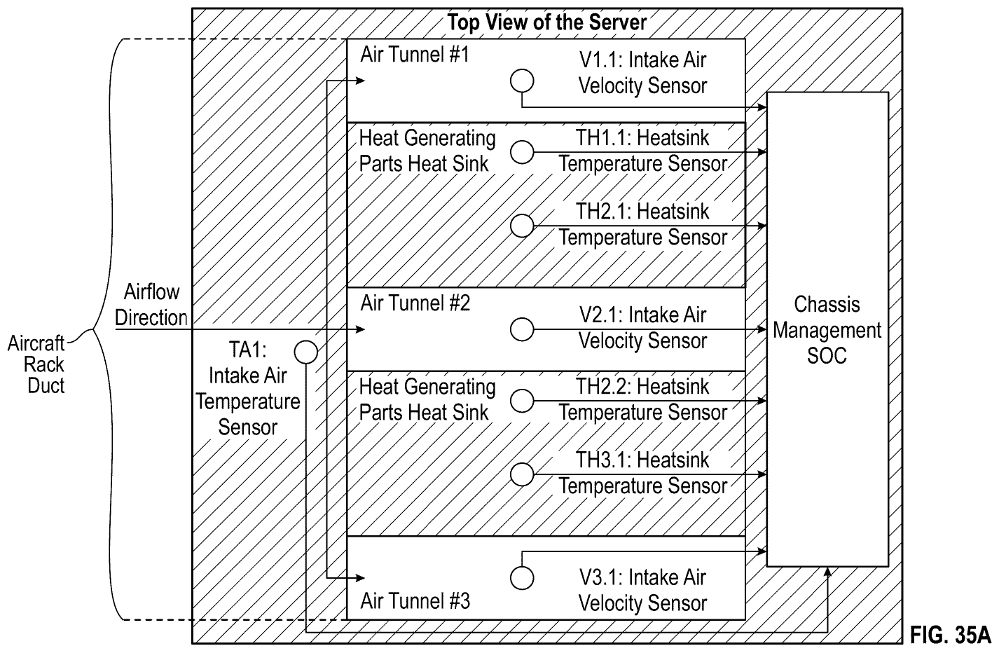

FIG. 34 is a schematic top view of the server illustrating airflow. As shown, a single stream of intake airflow can enter the server from the aircraft rack duct, and split into the three air tunnels, which are positioned adjacent to and/or in between the two modules (labeled as “Heat Generating Parts/Heat sink”).

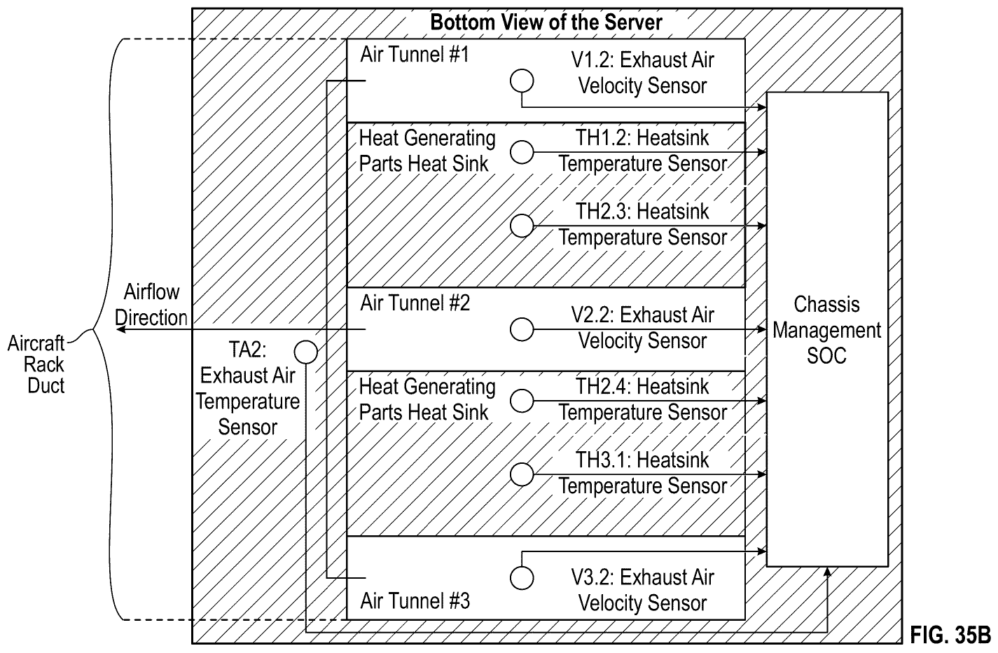

FIGS. 35A and 35B are schematic top and bottom views, respectively, of the server illustrating sensor positioning. Referring first to FIG. 35A, the intake air temperature sensor can be positioned upstream of the three air tunnels so that the sensor can measure the intake air temperature before the airflow splits into the three air tunnels. Also, one intake air velocity sensor can be positioned in each air tunnel and located closer to the intake ends than the exhaust ends (and thus illustrated in FIG. 35A, but not in FIG. 35B). Similarly, one intake heatsink temperature sensor can be positioned at each heat heatsink and located closer to the intake ends than the exhaust ends (and thus illustrated in FIG. 35A, but not in FIG. 35B). Because each module is a dual-complex having two heat sinks, a total of four intake heatsink temperature sensors are illustrated. Each of these sensors can be operably coupled to the chassis management SOC.

Referring next to FIG. 35B, one exhaust air velocity sensor can be positioned in each air tunnel and located closer to the exhaust ends than the intake ends (and thus illustrated in FIG. 35B, but not in FIG. 35A). Similarly, one exhaust heatsink temperature sensor can be positioned at each heat heatsink and located closer to the exhaust ends than the intake ends (and thus illustrated in FIG. 35A, but not in FIG. 35B). Because each module is a dual-complex having two heat sinks, a total of four exhaust heatsink temperature sensors are illustrated. The exhaust air temperature sensor can be positioned downstream of the three air tunnels so that the sensor can measure the exhaust air temperature after the airflows from the three air tunnels merge back into one stream. Each of these sensors can be operably coupled to the chassis management SOC.

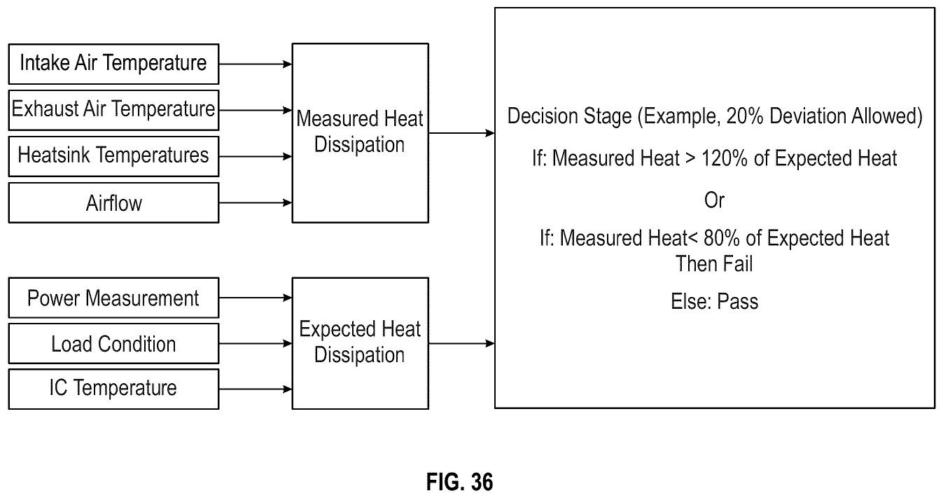

FIG. 36 is a schematic diagram illustrating data post-processing flow in accordance with various embodiments of the present technology. In particular, FIG. 36 illustrates an example algorithm that can be used by the chassis management SOC as part of the operations management system 3100 to detect temperature anomalies. As shown, the sensor measurements of the intake air temperature, the exhaust air temperature, the various heatsink temperatures, and the various airflow velocities can be used to calculate or otherwise determine a measured heat dissipation value. Separately, the sensor measurements of power consumptions, load conditions, and IC temperatures can be used to calculate or otherwise determine an expected heat dissipation value.

Then, the chassis management SOC (e.g., a processor thereof) can compare the measured heat dissipation value against the expected heat dissipation value. At a high level, if the measured heat dissipation value is greater than the expected heat dissipation value, this can indicate an internal component failure causing a short circuit, low impedance, and/or the like, resulting in excessive heat generation. Conversely, if the measured heat dissipation value is less than the expected heat dissipation value, this can indicate that the circuit is not functioning properly (e.g., not drawing enough power). Such deviations can also indicate sensor failure.

In the event that the measured heat dissipation value is greater than a first threshold percentage of the expected heat dissipation value or is less than a second threshold percentage of the expected heat dissipation value, the system 3100 can indicate an anomaly and respond accordingly. For example, the system 3100 may alert operators and/or shut off the servers to avoid more serious failures. Otherwise, if the measured heat dissipation value is within the first and second threshold percentages of the expected heat dissipation value, the system 3100 can indicate an absence of anomalies and allow the servers to continue to operate normally. The first and second threshold percentages can be set by an operator as appropriate. For example, the first threshold percentage can be about 105%, 110%, 115%, 120%, 125%, 130%, 135%, 140%, 145%, 150%, or between 105-150%, and the second threshold percentage can be about 95%, 90%, 85%, 80%, 75%, 70%, 65%, 60%, 55%, 50%, or between 50-95%.

In some embodiments, the expected heat dissipation value (P_{EHD}) can be calculated via Equation (1):

$${P}_{EHD} = {\sum }_{n = 1}^{n} r 1 \times {LF}_{n}^{2} + {\sum }_{m = 1}^{m} r 2 \times {P}_{m} + {\sum }_{i = 1}^{i} r 3 \times {T}_{i} + C \qquad ( 1 )$$

where LFₙ is the load factor from n^{th} sources, Pₘ is the power reading from m^{th} power sensors, Tᵢ is the temperature reading from the i^{th} temperature sensor, and r1, r2, r3, and C are constants from regression calculations. As an illustrative example, a server can include three core components: CPU, RAM, and SSD. The server can also include a circuit power meter and a temperature sensor. The load factors LFₙ of the three core components, the power reading Pₘ from the circuit power meter, and the temperature reading Tᵢ from the temperature sensor can be obtained. Once r1, r2, r3, and C are determined via regression calculations after LRU development, the expected heat dissipation value (P_{EHD}) can be calculated for that particular server.

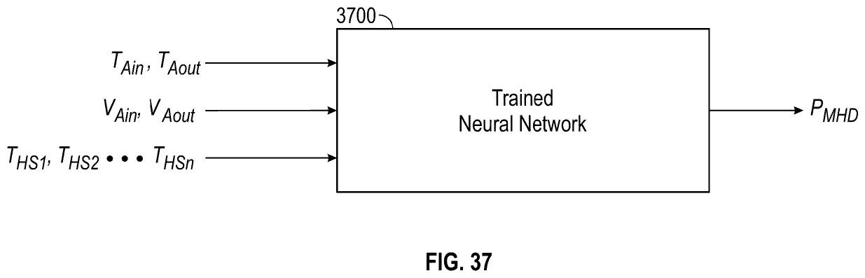

FIG. 37 is a schematic diagram illustrating operation of a trained neural network model 3700 configured in accordance with embodiments of the present technology. As shown, the trained neural network model 3700 can receive the sensor measurements of the intake air temperature, the exhaust air temperature, the various heatsink temperatures, and the various airflow velocities to calculate the measured heat dissipation value (P_{MHD}). The model 3700 (or other artificial intelligence model) can be trained to calculate the measured heat dissipation value (P_{MHD}) based at least in part on such sensor measurements. In other embodiments, however, the measured heat dissipation value (P_{MHD}) can be calculated using a polynomial regression calculation in a manner similar to how the expected heat dissipation value (P_{EHD}) is calculated, described above.

Accordingly, by comparing measured and expected heat dissipation values, the system 3100 can detect thermal anomalies with relatively low false-positive and false-negative rates. This is contrast to existing temperature management systems in which the system is triggered upon the measured temperature reaching or exceeding a fixed, predetermined threshold. When a system relies on a fixed, predetermined threshold, the system can result in relatively high false-positive and false-negative rates. For example, if the maximum threshold temperature is set at 95 degrees Celsius and the server is located in a region that experiences elevated temperatures regularly (e.g., Dubai), the system can result in false-positives. Conversely, if the server is located in a region that experience cold temperatures regularly (e.g., Finland in the winter), the server may never reach the maximum threshold temperature of 95 degrees Celsius even if the server is experiencing short circuiting or other modes of failure, leading to false-negatives.

It is appreciated that the server design and the thermal management systems and methods disclosed herein are not limited to servers onboard aircraft, and are applicable to servers located elsewhere (e.g., on the ground).

### 5. Example Solutions

Various technical solutions disclosed in the present document that may be adopted by some preferred embodiments include:

1. An electronic system, comprising: a chassis comprising at least one chassis processor, wherein the chassis is configured with N slots for accepting N electronic blades comprising zero or more of compute blades and zero or more of storage blades, where N is a positive integer greater than 1; wherein the at least one chassis processor is configured to provide a common operational interface between multiple types of aircrafts and the N electronic blades. Example embodiments are described with reference to FIGS. 7B and 7C.

2. The electronic system of solution 1, wherein each compute blade comprises at least two processors.

3. The electronic system of any of solutions 1-2, wherein each storage blade comprises at least two non-volatile storage memories.

4. The electronic system of any of solutions 2 or 3, wherein each compute blade and each storage blade is configured to be hot-swappable.

5. The electronic system of solution 1, wherein the electronic system comprises zero compute blades and at least two storage blades.

6. The electronic system of solution 1, wherein the electronic system comprises zero storage blades and at least two compute blades.

7. A method of operating electronic equipment, comprising: providing a chassis on an aircraft, wherein the chassis includes at least one chassis processor, wherein the chassis is configured with N slots for accepting N electronic blades comprising zero or more of compute blades and zero or more of storage blades, where N is a positive integer greater than 1; wherein the at least one chassis processor is configured to provide a common operational interface between multiple types of aircrafts and the N electronic blades; and populating the N slots with compute blades and/or storage blades according to a target configuration.

8. The method of solution 7, including: performing a modification to the target configuration by adding or removing an electronic blade without taking any of existing electronic blades in the chassis offline and without altering the chassis.

9. The method of solution 8, wherein, the at least one chassis processor is configured to bring an added electronic blade online by providing configuration information to the added electronic blade.

10. A headend server for use onboard a commercial aircraft, the headend server comprising: a chassis meeting specific size requirement such as a 6 Modular Concept Unit (MCU) size requirement (the number 6 may may pre-determined different number for different installations); a pair of modules insertable into and removable from the chassis, wherein each module includes a plurality of slots; one or more electronic blades shaped and sized to fit in corresponding ones of the plurality of slots; an input/output (I/O) interface module housed in the chassis; and a power supply integrated in the chassis, wherein each of the headend server and the pair of modules is a Line Replacement Unit (LRU), and wherein the headend server is configured to provide a common operational interface between multiple types of aircrafts and the one or more electronic blades.

11. The headend server of solution 10, wherein each of the one or more electronic blades includes a first unit occupying a first portion of the respective electronic blade and a second unit occupying a second portion of the respective electronic blade, wherein each of the first unit and the second unit includes a plurality of electronic components selected from a processor, a boot drive, a RAM, an SSD, an I/O interface, and a PCIe.

12. The headend server of solution 11, wherein the plurality of electronic components of the first unit and the plurality of electronic components of the second unit are arranged identically.

13. The headend server of solutions 10-12, wherein at least one of the pair of modules includes a mixed-use peripheral module, and wherein the one or more electronic blades include one or more AI accelerators and one or more non-volatile storage devices.

14. The headend server of solutions 10-13, wherein the one or more electronic blades include one or more compute blades having 32 cores and 64 threads.

15. The headend server of solutions 10-14, wherein the one or more electronic blades include one or more storage blades having between 32-96 TB of storage.

16. The headend server of solutions 10-15, wherein the chassis has dimensions of about 379 mm×190 mm×194 mm and a weight no more than 25 lbs.

17. The headend server of solutions 10-16, wherein each of the pair of modules has a height between 100-200 mm, a width between 50-100 mm, a length between 100-500 mm, and a weight no more than 7 lbs.

18. The headend server of solutions 10-17, further comprising one or more thermal sensors and/or one or more airflow sensors each housed in the chassis, wherein the one or more thermal sensors and/or the one or more airflow sensors are configured to indicate a maximum power usage of the pair of modules.

19. The headend server of solutions 10-18, wherein each of the pair of modules further includes a latch operable to lock the respective module within the chassis or release the respective module from the chassis, wherein the latch is operably without use of an additional tool.

20. The headend server of solutions 10-19, wherein the I/O interface module includes either a copper-based I/O interface module or a fiber-based I/O interface module, and wherein the I/O interface module is swappable.

21. The headend server of solutions 10-19, wherein the I/O interface module includes either a copper-based I/O interface module or a fiber-based I/O interface module, and wherein the I/O interface module is integrated with the chassis.

22. The headend server of solutions 10-21, wherein the pair of modules is configured to connect to both a private cluster network and a public network, wherein the pair of modules is configured to use the private cluster network for headend cluster-related traffic, and wherein the pair of modules is configured to use the public network for other in-flight entertainment traffic.

23. The headend server of solutions 10-22, wherein each of the one or more electronic blades includes at least two non-volatile storage memories.

24. The headend server of solutions 10-23, wherein each of the one or more electronic blades is configured to be hot-swappable.

25. The headend server of solutions 10-24, wherein the one or more electronic blades include zero compute blades and at least two storage blades.

26. The headend server of solutions 10-25, wherein the one or more electronic blades include zero storage blades and at least two compute blades.

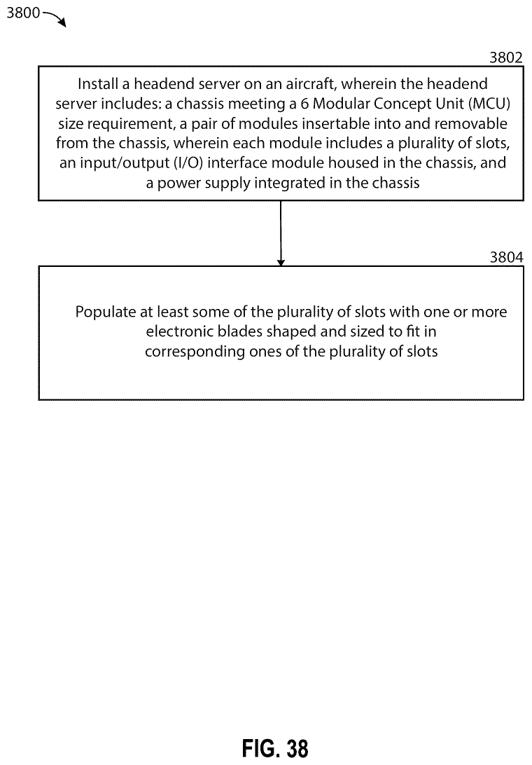

27. A method for operating a headend server onboard a commercial aircraft (e.g., method 3800 depicted in FIG. 38), the method comprising: installing (3802) a headend server on an aircraft, wherein the headend server includes: a chassis meeting a 6 Modular Concept Unit (MCU) size requirement, a pair of modules insertable into and removable from the chassis, wherein each module includes a plurality of slots, an input/output (I/O) interface module housed in the chassis, and a power supply integrated in the chassis; and populating (3804) at least some of the plurality of slots with one or more electronic blades shaped and sized to fit in corresponding ones of the plurality of slots, wherein each of the headend server and the pair of modules is a Line Replacement Unit (LRU), and wherein the headend server is configured to provide a common operational interface between multiple types of aircrafts and the one or more electronic blades.

28. The method of solution 27, further comprising: modifying the headend server to a target configuration by (i) adding an additional electronic blade to one of the plurality of slots and/or (ii) removing one of the one or more electronic blades from the plurality of slots, wherein the headend server is modified without taking remaining ones of the one or more electronic blades in the chassis offline and without altering the chassis.

29. The method of solution 27 or solution 28, wherein populating comprises selecting among compute blades, storage blades, and AI accelerators based at least in part on demands of the aircraft.

In some embodiments, a hardware platform includes a chassis that is configured to hold one or more electronic blades that may be inserted and pulled out from the chassis where the chassis comprises a groove or a track that allows insertion/removal of the electronic blades. The hardware platform may be defined by a front side and a back side. The front side may be made accessible to a human operator for inserting or removing the electronics blades. A turnable latch mechanism is provided (e.g., FIG. 20) that allows locking or unlocking of the electronic blades within the chassis. The latch mechanism may be mechanically coupled with one or more insertion points that are distributed along a length of the groove of the chassis such that turning the latch into a lock position causes the inserters to move in a positions and be inserted within corresponding receptacles on chassis, thereby securing the electronic blade in place and turning the latch into the unlocking position disengages the insertion points allowing removal or insertion of the electronic blade within the groove. Additional details are described with reference to FIGS. 18A to 35B.

In some solutions implemented by embodiments, the hardware platform may comprise a chassis with multiple tracks that allow insertion of multiple electronic blades. In some embodiments, the electronic blade may comprise a motherboard (e.g., a printed circuit board) that is substantially planar. On one side or surface of the motherboard, a first processor may be affixed using an intervening insulation material. On the other side of the motherboard, opposite to the first side, a second processor may be disposed with another intervening insulation material layer. Both processors may have heat sinks disposed over them in a direction away from the motherboard. The motherboard may extend beyond the insulation material layer such that portion of the motherboard exposed by this extension may be used to couple to storage modules that are disposed on either side of the mother board and communicatively coupled to one or both of the first and second processors.

Upon insertion of the electronic blade formed by the motherboard and above-described electronics, the heatsinks may be positioned to form an air tunnel, e.g., as depicted in FIGS. 30 to 35B. The design of the electronic blades may conform to one or more of the following features: (1) upon insertion, heatsinks of the electronic blades will face each other and form an air tunnel or air cavity from which air can pass over the heat sink and provide thermal cooling, (2) heatsinks may be configured with fins that are spaced according to thermal cooling requirements (3) thermal fins of heatsinks facing each other may be aligned, (4) thermal fins of heatsinks facing each other may be offset from each other, (5) heatsink surfaces facing each other are designed such that the airflow traveling over the heatsinks is laminar and is defined by an input port and an output port, (6) temperature sensors may be placed at the input and output ports and configured to sense local temperatures that are used to calculate a temperature differential between incoming air and outgoing air, (7) the density of thermal fins on a heatsink may be determined according to a cooling budget for corresponding electronic blade—for example denser or more used electronics may have a greater density of fins, allowing more surface area for cooling, compared to boards with electronics that generates less heat, (8) use a machine learning algorithm that is fed input and output temperatures captured from the sensors and is trained to determine if a thermal failure has occurred or is about to occur and raise an alarm to a human user or to the controller of the chassis such that load balancing can be performed by taking down the blade that may be overheating and load balancing software and storage to other electronic blades.

### CONCLUSION

It will be appreciated that the present document discloses a configuration that may be used for inflight entertainment servers (e.g., for systems as shown in FIGS. 1 to 3) that include a chassis that is configured to accept blades with compatible pinouts. The chassis may include one or more processors and a memory that are configured to execute a program by which the chassis provides a uniform interface to all blades that are inserted in slots in the chassis, regardless of details of the aircraft in which the chassis is installed. Such an abstraction of the hardware details of the aircraft allow for use of identical blades (e.g., compute boards or storage boards) in all aircrafts operated by an airlines.

In another advantageous aspect, the discloses methods allow for on-the-fly configuration of the inflight servers according to needs. For example, a blade may be a storage blade or a compute blade, and such blades may be mixed-and-matched according to needs on an aircraft. Such hardware compatibilities allow for easy maintenance and replacement where a technician can swap out a blade without having to make any changes to chassis. Once a new blade is inserted, the chassis processor performs the task of configuring the new blade with configuration information such that the new blade operates either to provide a new functionality or to be a replacement of the blade that was swapped out.

It will be appreciated that although aircraft examples are used in the present document, the disclosed methods may be used on any commercial passenger vehicles such as trains, tourists coaches, and the like.

The embodiments set forth herein represent the necessary information to enable those skilled in the art to practice the embodiments and illustrate the best mode of practicing the embodiments. Upon reading the description in light of the accompanying figures, those skilled in the art will understand the concepts of the disclosure and will recognize applications of these concepts that are not particularly addressed herein. These concepts and applications fall within the scope of the disclosure and the accompanying solutions.

The above description and drawings are illustrative and are not to be construed as limiting. Numerous specific details are described to provide a thorough understanding of the disclosure. However, in certain instances, well-known details are not described in order to avoid obscuring the description. Further, various modifications may be made without deviating from the scope of the embodiments.

As used herein, unless specifically stated otherwise, terms such as “processing,” “computing,” “calculating,” “determining,” “displaying,” “generating,” or the like, refer to actions and processes of a computer or similar electronic computing device that manipulates and transforms data represented as physical (electronic) quantities within the computer's memory or registers into other data similarly represented as physical quantities within the computer's memory, registers, or other such storage medium, transmission, or display devices.

Reference herein to “one embodiment” or “an embodiment” means that a particular feature, structure, or characteristic described in connection with the embodiment is included in at least one embodiment of the disclosure. The appearances of the phrase “in one embodiment” in various places in the specification are not necessarily all referring to the same embodiment, nor are separate or alternative embodiments mutually exclusive of other embodiments. Moreover, various features are described which may be exhibited by some embodiments and not by others. Similarly, various requirements are described which may be requirements for some embodiments but not for other embodiments. The term “about” shall mean within +10% of the stated value.

The terms used in this specification generally have their ordinary meanings in the art, within the context of the disclosure, and in the specific context where each term is used. Certain terms that are used to describe the disclosure are discussed above, or elsewhere in the specification, to provide additional guidance to the practitioner regarding the description of the disclosure. For convenience, certain terms may be highlighted, for example using italics and/or quotation marks. The use of highlighting has no influence on the scope and meaning of a term; the scope and meaning of a term is the same, in the same context, whether or not it is highlighted. It will be appreciated that the same thing can be said in more than one way.

Consequently, alternative language and synonyms may be used for any one or more of the terms discussed herein, nor is any special significance to be placed upon whether or not a term is elaborated or discussed herein. Synonyms for certain terms are provided. A recital of one or more synonyms does not exclude the use of other synonyms. The use of examples anywhere in this specification including examples of any term discussed herein is illustrative only and is not intended to further limit the scope and meaning of the disclosure or of any exemplified term. Likewise, the disclosure is not limited to various embodiments given in this specification.

Without intent to further limit the scope of the disclosure, examples of instruments, apparatus, methods and their related results according to the embodiments of the present disclosure are given above. Note that titles or subtitles may be used in the examples for convenience of a reader, which in no way should limit the scope of the disclosure. Unless otherwise defined, all technical and scientific terms used herein have the same meaning as commonly understood by one of ordinary skill in the art to which this disclosure pertains. In the case of conflict, the present document, including definitions will control.

From the foregoing, it will be appreciated that specific embodiments of the invention have been described herein for purposes of illustration, but that various modifications may be made without deviating from the scope of the invention. Accordingly, the invention is not limited except as by the appended claims.

From the foregoing, it will be appreciated that specific embodiments of the invention have been described herein for purposes of illustration, but that various modifications may be made without deviating from the scope of the invention. Accordingly, the invention is not limited except as by the appended claims.

What is claimed is:

1. An apparatus for use onboard a commercial aircraft, comprising:
a chassis comprising slots configured to accept one or more electronic blades from a front side of a hardware platform that is accessible to a human operator upon installation of the hardware platform in a commercial aircraft;
electronic blades shaped and sized to fit in corresponding ones of a plurality of slots; and
a latch mechanism that is turnable to allow locking or unlocking of the electronic blades within the chassis, wherein the latch mechanism is mechanically coupled with one or more insertion points that are distributed along a length of the chassis from the front side to a back side such that turning the latch mechanism into a lock position causes inserters to move in positions and be inserted within corresponding receptacles on the chassis, thereby securing the electronic blades in place and turning the latch into the unlocking position disengages the insertion points allowing removal or insertion of the electronic blades within the slots;
wherein the electronic blades comprises a motherboard having a first processor on one side of the motherboard and a second processor on an opposite side of the motherboard,
wherein, upon insertion of the electronic blades into the chassis, an air tunnel is formed within the chassis allowing air to flow through the air tunnel.

2. The apparatus of claim 1, wherein the first processor is affixed to the motherboard using an intervening insulation material and the second processor is affixed to the motherboard using an intervening insulation material, and wherein the first processor and the second processors have heat sinks disposed thereon in a direction away from the motherboard.

3. The apparatus of claim 2, wherein the electronic blades, upon insertion in the chassis, form the air tunnel from which air passed over the heat sinks.

4. The apparatus of claim 2, wherein the heat sinks are configured to include fins that are spaced to meet a thermal cooling requirement.

5. The apparatus of claim 4, wherein the fins and heat sinks of neighboring electronic blades facing each other are aligned with respect to each other.

6. The apparatus of claim 4, wherein the fins and heat sinks of neighboring electronic blades facing each other are offset with respect to each other.

7. The apparatus of claim 4, wherein heat sink surfaces facing each other are designed such that air traveling over the heat sink surfaces is laminar and is defined by an input port and an output port.

8. The apparatus of claim 7, further including temperature sensors placed at the input and output ports and configured to sense local temperatures that are used to calculate a temperature differential between incoming air and outgoing air in the air tunnel.

9. The apparatus of claim 2, wherein the heat sinks are configured to include fins wherein a density of the fins on a heat sink is according to a cooling budget for a corresponding electronic blade.

10. The apparatus of claim 8, wherein the temperature sensors are configured to feed input and output temperatures captured from the sensors to a machine learning algorithm that is trained to determine if a thermal failure has occurred or is about to occur and raise an alarm to a human user or to a controller of the chassis.

11. The apparatus of claim 1, wherein the electronic blades comprise an I/O interface module, wherein the I/O interface module includes either a copper-based I/O interface module or a fiber-based I/O interface module, and wherein the I/O interface module is swappable.

12. The apparatus of claim 11, wherein the I/O interface module includes either a copper-based I/O interface module or a fiber-based I/O interface module, and wherein the I/O interface module is integrated with the chassis.

13. The apparatus of claim 1, wherein the electronic blades comprise a pair of modules that is configured to connect to both a private cluster network and a public network, wherein the pair of modules is configured to use the private cluster network for headend cluster-related traffic, and wherein the pair of modules is configured to use the public network for other in-flight entertainment traffic.

14. The apparatus of claim 1, wherein each of the electronic blades includes at least two non-volatile storage memories.

15. The apparatus of claim 1, wherein each of the electronic blades is configured to be hot-swappable.

16. The apparatus of claim 1, wherein the electronic blades include zero compute blades and at least two storage blades.

17. The apparatus of claim 1, wherein the electronic blades include zero storage blades and at least two compute blades.

18. The apparatus of claim 1, wherein the electronic blades comprise printed circuit boards.

19. A method, comprising:
receiving, by a controller of a chassis, a determination from a machine learning algorithm that a thermal failure has occurred or is about to occur in an apparatus that includes the chassis,
wherein the apparatus is configured to operate onboard a commercial aircraft by providing:
wherein the chassis comprises slots configured to accept one or more electronic blades from a front side;
wherein the apparatus comprises:
electronic blades shaped and sized to fit in corresponding ones of a plurality of slots; and
a latch mechanism that is turnable to allow locking or unlocking of the electronic blades within the chassis, wherein the latch mechanism is mechanically coupled with one or more insertion points that are distributed along a length of the chassis from the front side to a back side such that turning the latch mechanism into a lock position causes inserters to move in positions and be inserted within corresponding receptacles on the chassis, thereby securing the electronic blades in place and turning the latch into the unlocking position disengages the insertion points allowing removal or insertion of the electronic blades within the slots;
wherein the electronic blades comprises a motherboard having a first processor on one side of the motherboard and a second processor on an opposite side of the motherboard,
wherein, upon insertion of the electronic blades into the chassis, an air tunnel is formed within the chassis allowing air to flow through the air tunnel;
wherein the machine learning algorithm that is fed input and output temperatures captured from sensors placed at input and output ports of the air tunnel, wherein the machine learning algorithm is trained to determine if the thermal failure has occurred or is about to occur and raise an alarm to a human user or to a controller; and
performing, by the controller, upon detection of the thermal failure, a load balancing by taking down a blade that is overheating.

20. The method of claim 19, further including:
performing, by the controller a load balancing of software and resources of the blade that is overheating with other electronic blades.
